(19) United States
(12) Patent Application Publication
(10) Pub. No.: US 2025/0038003 A1
(43) Pub. Date: Jan. 30, 2025

(54) LOW TEMPERATURE MOLYBDENUM DEPOSITION ASSISTED BY SILICON-CONTAINING REACTANTS

(71) Applicant: Lam Research Corporation, Fremont, CA (US)

(72) Inventors: David Joseph Mandia, Fremont, CA (US); Kyle Jordan Blakeney, Milpitas, CA (US); Chiukin Steven Lai, Sunnyvale, CA (US)

(73) Assignee: Lam Research Corporation, Fremont, CA (US)

(21) Appl. No.: 18/716,846

(22) PCT Filed: Dec. 2, 2022
(86) PCT No.: PCT/US2022/080863

§ 371 Date: Jun. 5, 2024

Related U.S. Application Data
(60) Provisional application No. 63/265,437, filed on Dec. 15, 2021.

(51) Int. Cl. H01L 21/285; C23C 16/42; C23C 16/455; C23C 16/52

(52) U.S. Cl. CPC H01L 21/28518; C23C 16/42; C23C 16/45544; C23C 16/45553; C23C 16/52

(57) ABSTRACT

Molybdenum-containing films are deposited on semiconductor substrates at relatively low temperatures of between about 100 and about 500° C., such as between about 200 and about 450° C. For example, molybdenum metal can be deposited at this temperature on a substrate having exposed metal and exposed dielectric in a substantially non-selective manner. In one implementation, a substrate having a recessed feature is provided, where the recessed feature has an exposed dielectric on the sidewalls and an exposed metal on the bottom. The substrate is exposed to a molybdenum-containing precursor, a reducing agent, and a silicon-containing reagent, to thereby reduce the molybdenum-containing precursor and form a molybdenum-containing layer that includes metallic molybdenum. The use of the silicon-containing reactant leads to a reduction in on-metal/on-dielectric selectivity of molybdenum deposition.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD OF THE INVENTION

This invention pertains to methods of semiconductor device manufacturing. Specifically, embodiments of this invention pertain to deposition of molybdenum-containing films in semiconductor processing.

### BACKGROUND

In semiconductor device fabrication, deposition and etching techniques are used for forming patterns of materials, such as for forming metal lines embedded in dielectric layers. Some patterning schemes require conformal deposition of materials, where the deposited layer should follow the contour of protrusions and/or recessed features on the surface of the substrate. Atomic layer deposition (ALD) is often a preferred method of forming conformal films on a substrate, because ALD relies on adsorption of one or more reactants (precursors) to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, this method can provide thin conformal layers having excellent step coverage.

Chemical vapor deposition (CVD) is another deposition method widely used in semiconductor processing. In CVD, the reaction occurs in the volume of the process chamber and is not limited by the amount of reactants adsorbed to the substrate. As a result, CVD-deposited films are often less conformal than ALD-deposited films. CVD is typically used in applications where step coverage is less important.

ALD and CVD may employ plasma to promote the reactions of the deposition precursors resulting in the formation of the desired films. The methods that make use of the plasma are known as plasma enhanced ALD (PEALD) and plasma enhanced CVD (PECVD). The methods that do not employ plasma are referred to as thermal ALD and thermal CVD.

While ALD and CVD are most commonly used for deposition of silicon-containing films, such as silicon oxide, silicon nitride, and silicon carbide, these methods are also suitable for deposition of some metals.

The background description provided herein is for the purposes of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

### SUMMARY

Methods for depositing metallic molybdenum via reduction of molybdenum-containing precursors at relatively low temperatures of between about 100 and about 500° C., are provided. The methods make use of silicon-containing reactants to improve reduction of molybdenum-containing precursors and/or to modulate selectivity of molybdenum deposition. In some embodiments, the methods are used to deposit molybdenum metal on a semiconductor substrate that includes different exposed materials (e.g., exposed metal and exposed dielectric) For example, molybdenum-containing layer may be substantially non-selectively deposited in a recessed feature that has exposed dielectric material at the sidewalls, and an exposed metal at the bottom. Provided molybdenum deposition methods can be used, for example, in gapfill applications. While provided methods are particularly useful for depositing molybdenum-containing layers, they can also be used to deposit other metals that have vaporizable precursors, such as cobalt, ruthenium, and tungsten.

In one aspect, a method of forming a molybdenum-containing layer on a semiconductor substrate is provided. The method involves: (a) providing a semiconductor substrate having a recessed feature to a process chamber; and (b) exposing the semiconductor substrate to a molybdenum-containing precursor, a reducing agent, and a silicon-containing reactant at a temperature of between about 100 and about 500° C. to reduce the molybdenum-containing precursor and form a molybdenum-containing layer on the semiconductor substrate, wherein the molybdenum-containing layer comprises a layer of molybdenum metal. In some embodiments the formed molybdenum-containing layer further includes a layer comprising a sub-layer of molybdenum silicide.

In some embodiments, the molybdenum-containing precursor is MoXₙYₘ, wherein X is a chalcogen, Y is a halogen, n is 0, 1, or 2, and m is 2, 3, 4, 5 or 6.

Examples of suitable molybdenum-containing precursors include MoCl₅, Mo₂Cl₁₀, MoO₂Cl₂, MoOCl₄, or any combination thereof.

In some embodiments, the silicon-containing reactant is SiₓR_{y}, wherein x is 1-4, y is 4-18, and each R is independently selected from the group consisting of H, a halogen, and an alkyl. Examples of suitable silicon-containing reactants include silane, chlorosilane, dichlorosilane, trichlorosilane, tetrachlorosilane, hexachlorodisilane, pentachlorodisilane, tetrachlorodisilane, trichlorodisilane dichlorodisilane, chlorodisilane, disilane or any combination thereof.

In one implementation, the reducing agent is hydrogen (H₂) and exposure of the semiconductor substrate to the molybdenum-containing precursor, the reducing agent, and the silicon-containing reactant includes: (i) contacting the semiconductor substrate with the silicon-containing reactant for a period of time without delivering the molybdenum-containing precursor to the process chamber; and (ii) after (i), contacting the semiconductor substrate with the molybdenum-containing precursor and with H₂. In some embodiments the semiconductor substrate is contacted with the molybdenum-containing precursor without contemporaneously delivering hydrogen to the process chamber. In other embodiments, the semiconductor substrate is contemporaneously contacted with the molybdenum-containing precursor and with hydrogen. In some embodiments the deposition method includes repeating steps (i) and (ii). In some embodiments step (ii) includes sequentially contacting the semiconductor substrate with the molybdenum-containing precursor and with hydrogen, and repeating the sequential contacting with the molybdenum-containing precursor and hydrogen. In some embodiments the method further includes: (iii) contacting the semiconductor substrate with the silicon-containing reactant after step (ii).

In some implementations, the reducing agent is hydrogen (H₂) and exposure of the semiconductor substrate to the molybdenum-containing precursor, the reducing agent, and the silicon-containing reactant includes: contemporaneously contacting the semiconductor substrate with hydrogen, the molybdenum-containing precursor and the silicon-containing reactant.

In some implementations, the reducing agent is hydrogen (H₂) and exposure of the semiconductor substrate to the molybdenum-containing precursor, the reducing agent, and the silicon-containing reactant includes: (i) contacting the semiconductor substrate with hydrogen and with the silicon-containing reactant contemporaneously, and (ii) contacting the semiconductor substrate with the molybdenum-containing precursor without contemporaneously delivering the silicon-containing reactant to the process chamber.

In some implementations, the reducing agent is hydrogen (H₂) and exposure of the semiconductor substrate to the molybdenum-containing precursor, the reducing agent, and the silicon-containing reactant includes: (i) contacting the semiconductor substrate with the molybdenum-containing precursor and with the silicon-containing reactant contemporaneously; and (iii) contacting the semiconductor substrate with hydrogen without delivering the silicon-containing reactant to the process chamber.

In some embodiments the recessed feature provided on the semiconductor substrate includes an exposed silicon-containing dielectric on sidewalls of the recessed feature, and a metal (e.g., tungsten or cobalt) exposed at a bottom of the recessed feature, wherein the molybdenum-containing layer is deposited both on the bottom of the recessed feature and on the sidewalls of the recessed features with a selectivity of about 1.3:1 (bottom to sidewalls) or less. In some embodiments the method includes completely filling the recessed feature with the molybdenum-containing layer, wherein the molybdenum-containing layer comprises a molybdenum metal layer.

In some embodiments the methods provided herein are integrated with photolithographic processing. For example, the methods may include the steps of: applying photoresist to the semiconductor substrate; exposing the photoresist to light; patterning the photoresist and transferring the pattern to the semiconductor substrate; and selectively removing the photoresist from the semiconductor substrate. For example, such photolithographic patterning may be used to form recessed features on the substrate prior to deposition of the molybdenum-containing material.

In another aspect, an apparatus for processing a semiconductor substrate is provided, where the apparatus includes (a) a process chamber, having a substrate holder for holding the semiconductor substrate and one or more inlets for introduction of reactants to the process chamber; and (b) a controller comprising program instructions for causing performance of any of the methods provided herein. For example, program instructions may include instructions for: on a semiconductor substrate having a recessed feature, causing contact of the semiconductor substrate with a molybdenum-containing precursor, a reducing agent, and a silicon-containing reactant at a temperature of between about 100 and about 500° C. to form a layer of molybdenum-containing material. For example, in some embodiments, the program instructions may be configured to cause: (i) contacting of the semiconductor substrate with a silicon-containing reactant without contemporaneously delivering the molybdenum containing precursor to the process chamber; and (ii) after (i) contacting the semiconductor substrate with the molybdenum-containing precursor and hydrogen. In some embodiments the program instructions include instructions configured to cause: (i) contemporaneously contacting the semiconductor substrate with hydrogen and the silicon-containing reactant without delivering the molybdenum-containing precursor to the process chamber; and (ii) contacting the semiconductor substrate with the molybdenum-containing precursor without contemporaneously delivering the silicon-containing reactant to the process chamber. In some embodiments, the program instructions comprise instructions configured to cause: (i) contemporaneously contacting the semiconductor substrate with the molybdenum-containing precursor and with the silicon-containing reactant without contemporaneously delivering hydrogen to the process chamber; and (ii) contacting the semiconductor substrate with hydrogen without contemporaneously delivering the silicon-containing reactant to the process chamber.

In another aspect computer machine readable medium is provided that includes code for causing steps of any of the methods provided herein. For example, code may be provided for: on a semiconductor substrate having a recessed feature, causing contact of the semiconductor substrate with a molybdenum-containing precursor, a reducing agent, and a silicon-containing reactant at a temperature of between about 100 and about 500° C. to form a layer of molybdenum-containing material.

In another aspect, a system that includes an apparatus described herein and a stepper is provided.

In another aspect, a method of forming a metal-containing layer (e.g., molybdenum, tungsten, cobalt, or ruthenium containing layer) on a semiconductor substrate, is provided. In some embodiments the method includes: (a) providing a semiconductor substrate having a recessed feature to a process chamber; and (b) exposing the semiconductor substrate to a metal precursor (e.g., molybdenum precursor, tingsten precursor, cobalt precursor, or ruthenium precursor), a reducing agent, and a silicon-containing reactant at a temperature of between about 100 and about 500° C. to reduce the metal precursor and form a metal-containing layer on the semiconductor substrate, wherein the metal-containing layer comprises a layer of metal (e.g., molybdenum, tungsten, cobalt, or ruthenium) in zero oxidation state. In some embodiments, the metal-containing layer further includes a layer of metal silicide (e.g., molybdenum silicide, tungsten silicide, cobalt silicide, or ruthenium silicide).

These and other aspects of implementations of the subject matter described in this specification are set forth in the accompanying drawings and the description below.

### BRIEF DESCRIPTION OF THE DRAWINGS

FIGS. 1A-1C illustrate schematic cross-sectional views of a substrate during deposition of molybdenum-containing films according to an embodiment provided herein.

FIG. 2A is a process flow diagram for a method of forming molybdenum-containing films according to an embodiment provided herein.

FIG. 2B is a process flow diagram for a method of forming molybdenum-containing films according to an embodiment provided herein.

FIG. 2C is a process flow diagram for a method of forming molybdenum-containing films according to an embodiment provided herein.

FIG. 2D is a process flow diagram for a method of forming molybdenum-containing films according to an embodiment provided herein.

FIG. 3 is a process flow diagram for a method of forming molybdenum-containing films according to an embodiment provided herein.

FIG. 4 provides examples of ligands that can be used in molybdenum precursors according to an embodiment provided herein.

FIG. 5 provides examples of sulfur-containing ligands that can be used in molybdenum precursors according to an embodiment provided herein.

FIG. 6 lists examples of molybdenum precursors according to an embodiment provided herein.

FIG. 7 is a schematic presentation of an apparatus that is suitable for depositing molybdenum-containing films, according to an embodiment provided herein.

FIG. 8 shows a schematic view of a multi-station processing system according to an embodiment provided herein.

FIG. 9 shows a schematic view of a multi-station processing system according to an embodiment provided herein.

FIG. 10A is an experimental plot for a comparative example illustrating on-metal/on-dielectric molybdenum metal deposition selectivity at different temperatures for silicon-free deposition.

FIG. 10B is an experimental plot illustrating on-metal/on-dielectric molybdenum-containing layer deposition selectivity at 400° C. for silicon-assisted deposition as a function of SiH₄ pre-soak time, in accordance with embodiments presented herein.

### DETAILED DESCRIPTION OF THE PREFERRED EMBODIMENTS

Methods for depositing molybdenum-containing films on semiconductor substrates at a relatively low temperature of less than about 550° C. such as between about 100° C. and about 500° C., between about 200° C. and about 450° C., or between about 375° C. and about 450° C., are provided. The methods can be used, for example, to deposit metallic molybdenum layers and/or molybdenum silicide layers. In some embodiments the methods are used to form a thin molybdenum silicide layer on a substrate, followed by deposition of a thicker metallic molybdenum layer. Provided methods can be used, for example, for depositing a blanket molybdenum-containing layer on a planar substrate, for depositing a conformal molybdenum-containing layer on a substrate having one or more recessed or protruding features, and for filling recessed features with molybdenum-containing materials.

In some embodiments provided methods utilize reduction of a molybdenum-containing precursor with a reducing agent, and additionally employ a silicon-containing reactant to assist in the reduction process. In some embodiments, provided methods utilize reduction of a molybdenum-containing precursor with a reducing agent, and additionally employ a silicon-containing reactant to modulate selectivity of deposition. It was discovered that silicon-containing reactants can be used to minimize selectivity of deposition of molybdenum-containing layers on a substrate having different exposed materials, such as both metallic and dielectric portions. In some embodiments, the use of a silicon-containing reactant in the deposition process results in a substantially non-selective deposition, whereas in an absence of the silicon-containing reactant, molybdenum would typically deposit on exposed metal portions of a substrate at a substantially higher rate than on dielectric portions.

Provided methods can be used in a variety of applications including but not limited to deposition of molybdenum metal in gapfill applications, formation of conformal metallic molybdenum films, formation of molybdenum silicide. Examples of semiconductor device structures that can be manufactured using provided methods include back end of the line (BEOL) metallization structures, front end of the line (FEOL) metallization structures, logic metallization structures, and memory structures, such as 3D NAND and DRAM. For example, provided methods can be used for molybdenum silicide formation in 3D DRAM structure fabrication, and for molybdenum metallization in buried wordline DRAM. In some embodiments the methods are used to deposit molybdenum-containing films having thicknesses ranging from between about 0.5 nm to about 4 nm, and can be used for depositing molybdenum metal in a variety of recessed features, such as features with widths of between 5 about 1 nm and about 25 nm, depths of between about 30 nm and about 200 nm or more and a variety of aspect ratios including high aspect ratios of at least 10:1, such as 30:1.

While methods provided herein are primarily illustrated with reference to deposition of molybdenum-containing layers, they can be used for deposition of other metals that have vaporizable precursors, such as tungsten, cobalt, and ruthenium. For example, in another aspect, a method of forming a metal-containing layer (e.g., molybdenum, tungsten, cobalt, or ruthenium containing layer) on a semiconductor substrate, is provided. In some embodiments the method includes: (a) providing a semiconductor substrate having a recessed feature to a process chamber; and (b) exposing the semiconductor substrate to a metal precursor (e.g., molybdenum precursor, tingsten precursor, cobalt precursor, or ruthenium precursor), a reducing agent, and a silicon-containing reactant at a temperature of between about 100 and about 500° C. to reduce the metal precursor and form a metal-containing layer on the semiconductor substrate, wherein the metal-containing layer comprises a layer of metal (e.g., molybdenum, tungsten, cobalt, or ruthenium) in zero oxidation state. In some embodiments, the metal-containing layer further includes a layer of metal silicide (e.g., molybdenum silicide, tungsten silicide, cobalt silicide, or ruthenium silicide).

“Molybdenum metal” or “metallic molybdenum” as used herein, refers to material that consists essentially of molybdenum (Mo) in zero oxidation state. Other elements (e.g., C, N, or O) can be present in molybdenum metal in small quantities (e.g., with a total content of less than about 15 atomic %, or less than about 10%, where hydrogen is not included in the calculation). “High purity molybdenum metal” as used herein refers to molybdenum metal that includes less than about 5% of other elements, such as less than about 1% of other elements, where hydrogen is not included in the calculation. In some embodiments, molybdenum metal deposited by provided methods includes at least a portion that is at least about 90% such as at least about 95%, or at least about 99% pure molybdenum, where % refer to weight percent.

Molybdenum silicide (MoSiₓ) refers to a material that consists essentially of molybdenum and silicon, where x indicates that the stoichiometry may vary. Other elements may be present in molybdenum silicide in small quantities, e.g., in an amount of less than about 10% atomic, where hydrogen is excluded from the calculation.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

A “reducing agent”, as used herein, refers to a reactant that loses one or more electrons in a reaction.

“Heteroleptic complexes”, as used herein, refer to compounds that contain at least two different ligands attached to a metal center.

“Homoleptic complexes”, as used herein, refer to compounds that contain all identical ligands attached to a metal center.

As used herein, the term “about” means +/−10% of any recited value, unless otherwise specified. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

“Substantially non-selective deposition” as used herein refers to deposition, in which the ratio of deposition rate on a first surface to deposition rate on a second surface (selectivity) is between about 0.7 and about 1.3. For example, the selectivity of substantially non-selective deposition may be about 0.9-1.1.

The term “silicon-assisted deposition” as used herein refers to deposition that employs exposure of the substrate to a silicon-containing reactant in the deposition process. Exposure of the substrate to a silicon-containing reactant, a molybdenum-containing precursor, and a reducing agent to deposit molybdenum metal and/or molybdenum silicide is an example of a silicon-assisted deposition.

The term “silicon-free deposition” as used herein, refers to deposition that does not make use of silicon-containing reactants. Exposure of the substrate to a molybdenum-containing precursor and a reducing agent without exposure to silicon-containing reactant to deposit molybdenum metal is an example of a silicon-free deposition.

The term “sub-layer” as used herein refers to any portion of a larger layer. For example, a layer of a molybdenum-containing material may include a sub-layer of molybdenum metal and a sub-layer of molybdenum silicide.

As used herein, the phrase at least one of A. B. and C should be construed to mean a logical (A OR B OR C), using a non-exclusive logical OR, and should not be construed to mean ‘at least one of A, at least one of B, and at least one of C.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group. (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane n-electrons corresponds to the Huckel rule (4π+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently. H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L¹ is a covalent bond or alkyl; and each of R¹ and R² is, independently. H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl), (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen. (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl. (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl. (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl.” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “chalcogen” is meant, O, S, Se or Te.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently. H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

Other features and advantages of the invention will be apparent from the following deception and the claims.

### Embodiments

In some embodiments, the deposition method involves: providing a semiconductor substrate having a recessed feature to a process chamber; and exposing the semiconductor substrate to a molybdenum-containing precursor, a reducing agent, and a silicon-containing reactant at a temperature of between about 100° C. and about 500° C. to form a molybdenum-containing layer on the semiconductor substrate, where the molybdenum-containing layer includes a layer of molybdenum metal, or a layer of molybdenum silicide or a combination of a layer of molybdenum metal and a layer of molybdenum silicide. In some implementations, the deposited molybdenum-containing layer includes both molybdenum silicide (e.g., formed in the beginning of deposition at an interface with other layers of the substrate) and molybdenum metal (e.g., deposited after molybdenum silicide has formed). In some embodiments the deposition is conducted at a temperature of between about 200° C. and about 450° C., such as at between about 375° C. and 450° C. The pressure during deposition can range, for example, between about 0.1 torr and about 100 torr, such as between about 10 torr and about 100 torr. The deposition can be performed in a CVD or ALD process chamber (or multiple process chambers), and does not require activation of reactants with a plasma (i.e., the entire deposition can be performed thermally). The molybdenum-containing precursor (or partially reduced molybdenum-containing precursor) during deposition is reduced by the reducing agent (e.g., to molybdenum metal), whereas the role of the silicon-containing reactant is at least one of facilitating the reduction reaction (e.g., by reducing the molybdenum in the precursor to a lower oxidation state) and modulating the selectivity of deposition. In some embodiments, the silicon-containing reactant both facilitates the reduction and modulates the selectivity of deposition.

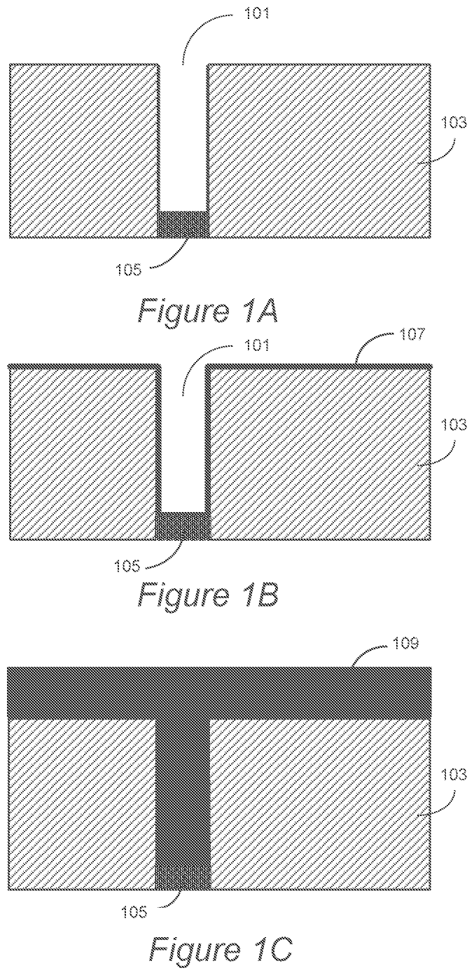

While provided method can be used on a variety of substrates, in some embodiments the method is used on substrates having recessed features that have different exposed materials at sidewalls and at the bottom. For example, in some embodiments the substrate has a recessed feature with an exposed metal on the bottom and with exposed dielectric on the sidewalls. FIG. 1A illustrates a schematic cross-sectional view of a portion of such substrate provided for deposition of molybdenum metal. The substrate has a recessed feature 101 formed in a layer of dielectric 103, where at the bottom of recessed feature 101, a layer of metal 105 is exposed. The dielectric layer 103 may include, for example, a silicon-containing dielectric, such as silicon oxide, silicon nitride, silicon oxynitride, silicon carbide, silicon oxycarbide and the like. The layer of metal 105 may include, for example, tungsten, copper, cobalt, molybdenum, etc. In one example, the dielectric material in dielectric layer 103 is silicon oxide and the metal layer 105 is a tungsten layer. While provided methods can be used for deposition of molybdenum-containing materials in a variety of different recessed features, they are particularly useful for deposition in features with aspect ratios of at least about 10:1, such as at least 30:1, or at least 50:1, as it is difficult to deposit molybdenum in a conformal manner at low temperature in high aspect ratio features. The methods can be used for deposition of conformal thin molybdenum-containing layers (e.g., 1-10 nm thick) and/or for filling recessed features with molybdenum metal, e.g, using a conformal fill.

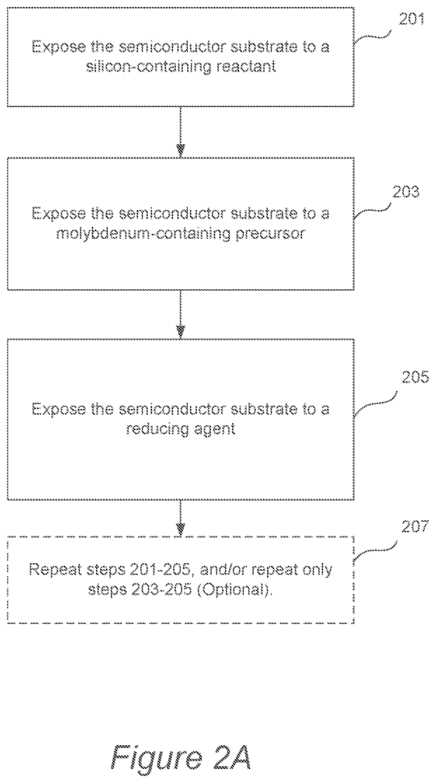

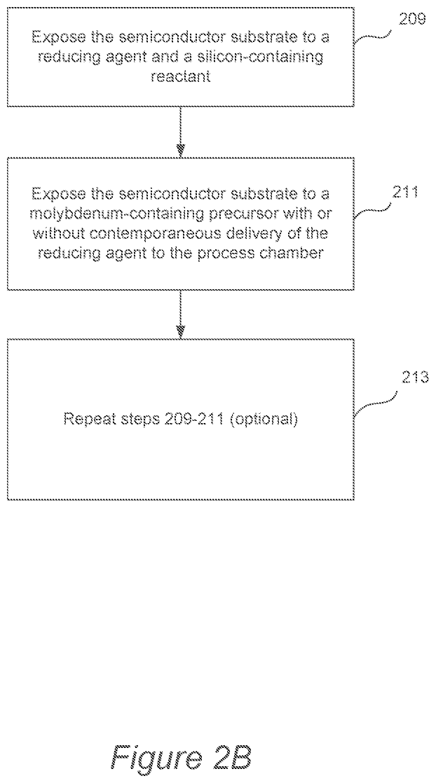

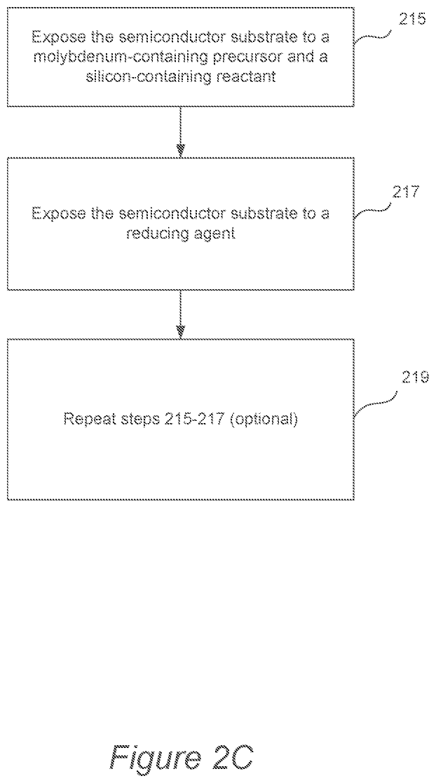

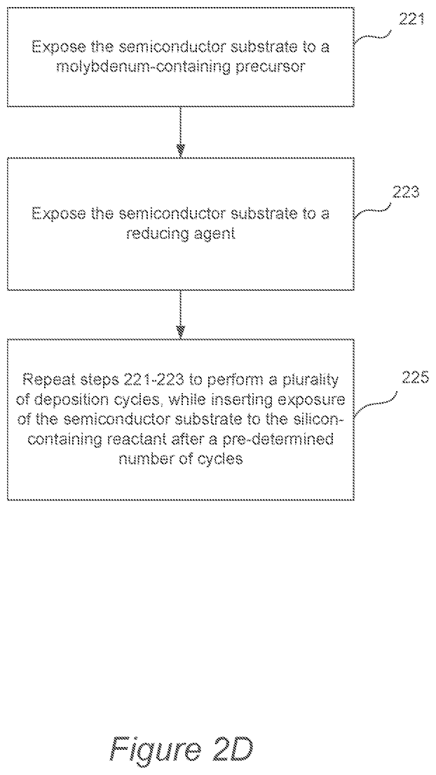

When molybdenum is deposited in an absence of a silicon-containing reactant, it would predominantly deposit on the metal layer, rather than on the dielectric layer, thereby leading to non-conformal coverage. For example selectivity of molybdenum metal deposition of 10 and higher (referring to on-metal deposition rate to on-dielectric deposition rate ratio) is observed at 375° C., leading to thick bottom coverage and thin sidewall coverage. While the deposition selectivity can be reduced by raising deposition temperature to 500° C. or more, it is noted that molybdenum metal deposition at high temperatures is often not desired due to thermal budget constraints. Introduction of a silicon-containing reactant was found to dramatically lower the deposition selectivity at lower temperatures of about 450° C. or less, such as at temperatures of between about 375° C. and about 450° C., thereby providing an avenue for conformal deposition of molybdenum-containing layers at relatively low temperatures. In some embodiments, in order to achieve the desired selectivity loss, the substrate is exposed to a silicon containing reactant prior to contact with the molybdenum-containing precursor. For example, the substrate may be exposed to a silicon-containing reactant for at least about 10 seconds, such as at least about 15 seconds to allow for surface modification. In some embodiments the exposure to silicon-containing reactant and the molybdenum-containing precursor is sequential. The structure formed after substantially non-selective deposition of molybdenum, according to methods provided herein, is shown in FIG. 2B. After the substrate is exposed to a molybdenum-containing precursor, a reducing agent, and a silicon-containing reactant, a substantially conformal layer of molybdenum-containing material 107, is formed, where the molybdenum-containing material 107 includes molybdenum metal, molybdenum silicide or a combination thereof. In some embodiments the molybdenum-containing layer 107 includes a molybdenum metal layer and a molybdenum silicide sublayer, where molybdenum silicide sublayer is formed at an interface between the substrate dielectric layer 103 and a molybdenum metal layer, and between the substrate metal layer 105 and the molybdenum metal layer. The process may then follow to fill the recessed feature 101 with a molybdenum-containing layer 109. In some embodiments, the molybdenum-containing layer 109 is molybdenum metal, which may be deposited using methods provided herein by exposing the semiconductor substrate to a molybdenum-containing precursor, a reducing agent, and a silicon-containing precursor. In other embodiments the bulk of molybdenum-containing layer 109 is molybdenum metal deposited without addition of silicon-containing reactants and involves exposure of the substrate to molybdenum-containing precursor and a silicon-containing reactant in a silicon-free deposition.

The selectivity reduction in some embodiments is due to direct modification of the substrate surface by the silicon-containing reactant. For example, when the dielectric layer 103 is a silicon-containing dielectric, such as silicon oxide, the silicon-containing reactant can modify the dielectric to form Si—H and/or Si—OH bonds, which may serve as nucleation sites for molybdenum-containing layer deposition, thereby increasing deposition rate on the sidewalls and reducing on-dielectric/on-metal deposition selectivity.

While the illustrated example referred to reduction of selectivity achieved by silicon-assisted deposition, the provided methods are not limited by this advantage. In some embodiments, silicon-assisted deposition is used to assist the reduction process without regard to selectivity.

The process of depositing molybdenum-containing layers with addition of silicon-containing reactants, provided herein, can be carried out using a variety of processing sequences. In some. CVD-type implementations, the molybdenum-containing precursor, the reducing agent, and the silicon-containing reactant are flowed into the process chamber contemporaneously (such that there is at least some overlap in time during flow of all three components), and are allowed to mix in the process chamber. In other, ALD-type implementations at least two components of the three (of the silicon-containing reactant, the molybdenum-containing precursor, and the reducing agent) are not flowed into the process chamber contemporaneously (such that there is no overlap in delivery time). These implementations may include several substrate exposure phases forming a single deposition cycle, where the deposition cycle is repeated as many times as needed to deposit a molybdenum-containing layer of desired thickness.

In some embodiments the process is carried out such that the silicon-containing reactant and the molybdenum-containing precursor are not delivered to the process chamber contemporaneously. In some embodiments the process is carried out such that the silicon-containing reactant and the reducing agent are not delivered to the process chamber contemporaneously. In some embodiments the process is carried out such that the molybdenum-containing reactant and the reducing agent are not delivered to the process chamber contemporaneously. In some embodiments the process is carried out such that the silicon-containing reactant, the molybdenum-containing reactant and the reducing agent are each delivered to the process chamber without temporal overlap.

One implementation of a deposition process is illustrated in FIG. 2A. The illustrated process is particularly useful for modulating selectivity of deposition on the substrate, because it starts with exposure of the substrate (e.g., of a substrate having exposed metal and dielectric such as shown in FIG. 1A) to the silicon-containing reactant, where the silicon-containing reactant can modify the surface of the substrate. Referring to FIG. 2A, the process starts in 201 by exposing the semiconductor substrate to a silicon-containing reactant. In some embodiments, step 201 involves delivering the silicon-containing reactant to the process chamber without contemporaneously delivering the molybdenum-containing precursor to the process chamber. A reducing agent may be optionally delivered to the process chamber contemporaneously with the silicon-containing reactant at this stage. The substrate, in some embodiments, is allowed to be exposed to the silicon-containing reactant for some time, such as at least about 10 seconds, such as at least about 15 seconds, at least about 20 seconds, or at least about 30 seconds to allow surface modification to take place.

Next, in step 203 the substrate is exposed to a molybdenum-containing precursor. In the illustrated embodiment, the molybdenum-containing precursor is delivered to the process chamber while there is no contemporaneous delivery of the silicon-containing reactant at this stage. A reducing agent may be optionally delivered contemporaneously with the molybdenum-containing precursor in step 203. Next, in step 205, the substrate is exposed to a reducing agent to reduce the molybdenum-containing precursor. In the depicted example, in this stage, the reducing agent is delivered to the process chamber without contemporaneously delivering the molybdenum-containing precursor and without contemporaneously delivering the silicon-containing reactant. The completion of steps 201-205 constitutes one deposition cycle. As shown in step 209, the steps 201-205 are then optionally repeated (e.g., at least 5 times, at least 10 times, or at least 100 times) and/or only silicon-free steps 203-205 are repeated (e.g., at least 5 times, at least 10 times, or at least 100 times) until a molybdenum-containing layer of desired thickness is formed. In some embodiments, after the initial one or more cycles of steps 201-205 are performed, only cycles of steps 203-205 are repeated, and the silicon-containing precursor exposure step 201, is inserted after a pre-determined number of cycles, e.g., after each 5 cycles or after each 10 cycles. In one example of the implementation of the process of FIG. 2A, the deposition involves: starting delivery of the silicon-containing reactant to the process chamber without delivering the reducing agent or molybdenum-containing precursor; after a period of flow, stopping delivery of the silicon-containing reactant; after delivery of the silicon-containing reactant is stopped, starting delivery of the molybdenum-containing precursor; then stopping delivery of the molybdenum-containing precursor; starting delivery of the reducing agent and stopping delivery of the reducing agent. In a modification of this implementation, the reducing agent is allowed to flow contemporaneously with the molybdenum-containing precursor and continues to flow to the process chamber after the delivery of the molybdenum-containing precursor is stopped.

Another embodiment of the deposition process is illustrated by the process flow diagram shown in FIG. 2B. In this implementation the process includes step 209, in which the substrate is exposed to the reducing agent and the silicon-containing reactant. In this step the reducing agent and the silicon-containing reactant are delivered contemporaneously into the process chamber in an absence of delivery of the molybdenum-containing precursor. Next, in step 211 the substrate is exposed to the molybdenum-containing precursor with or without contemporaneous exposure to the reducing agent. In the depicted illustration, step 211 is conducted without contemporaneous exposure of the semiconductor substrate to the silicon-containing reactant. In other embodiments, the silicon-containing reactant may be delivered during step 211 as well. Next, in step 213, steps 209-211 which constitute one deposition cycle are repeated as many times as needed to form a molybdenum-containing layer of desired thickness.

In some embodiments the silicon-containing reactant is delivered contemporaneously with the molybdenum-containing precursor. This is illustrated by the process diagram shown in FIG. 2C. This process begins in step 215 by exposing the semiconductor substrate to the molybdenum-containing precursor and the silicon-containing reactant. For example, the molybdenum-containing precursor and the silicon-containing reactant can be contemporaneously delivered to the process chamber housing the substrate. Step 215 can be conducted with or without contemporaneous delivery of reducing agent. Next, in step 217, the semiconductor substrate is exposed to a reducing agent. The reducing agent can be delivered to the process chamber with or without contemporaneous delivery of the silicon-containing reactant, and with or without contemporaneous delivery of the molybdenum-containing precursor. Next, in step 219, steps 215-217 are repeated as many times as needed to form a molybdenum-containing film of a desired thickness.

It is noted that all provided processes may optionally include purging steps after any of the exposure steps to remove undesired reactants and/or byproducts from the process chamber. In some embodiments purging is conducted by flowing an inert gas (e.g., argon, helium, nitrogen, etc.). In other embodiments, no dedicated purging steps with an inert gas are used, and purging is conducted by flowing the reducing agent (e.g., hydrogen). It is noted that the order of exposure steps can be switched as desired, although in some implementations it is preferable to expose the substrate containing an exposed dielectric layer and a metal layer to the silicon-containing reactant prior to exposure to molybdenum-containing precursor in order to modify the surface of the substrate and achieve desired selectivity loss.

In some embodiments, the exposure to the silicon-containing reactant is used after one or more silicon-free deposition cycles have been performed. For example, a molybdenum-containing layer may be deposited as shown in the process flow diagram of FIG. 2D. In step 221 the semiconductor substrate is exposed to a molybdenum-containing precursor and in step 223 the semiconductor substrate is exposed to the reducing agent. Both of these steps are performed in an absence of a silicon-containing reactant and constitute one silicon-free molybdenum metal deposition cycle. In step 225, steps 221-223 are repeated to perform a plurality of deposition cycles while inserting exposure of the substrate to a silicon-containing reactant after a pre-determined number of silicon-free molubdenum metal deposition cycles. For example, the substrate may be exposed to the silicon-containing reactant as a single exposure after every 5, 10, 20, or 50 silicon-free deposition cycles. Alternatively, one or more silicon-assisted deposition cycles, such as any of illustrated in FIGS. 2A-2C, may be inserted after a predetermined number of silicon-free cycles.

In some embodiments, the molybdenum-containing layer deposition involves depositing molybdenum-containing material (e.g., molubdenum silicide and/or molybdenum metal) using silicon-assisted deposition as described herein, followed by deposition of molybdenum metal using silicon-free deposition. For example, 2-2,000 silicon-assisted deposition cycles may be followed by 2-2,000 silicon-free deposition cycles. In some embodiments this process flow is used to deposit a molybdenum-containing layer that includes a molybdenum silicide layer at an interface with a silicon-containing dielectric and then form a molybdenum metal layer over the molybdenum silicide layer. The molybdenum silicide layer of the molybdenum-containing layer may be deposited using silicon-assisted deposition, and the molybdenum metal layer of the molybdenum-containing layer may be deposited using silicon-free deposition.

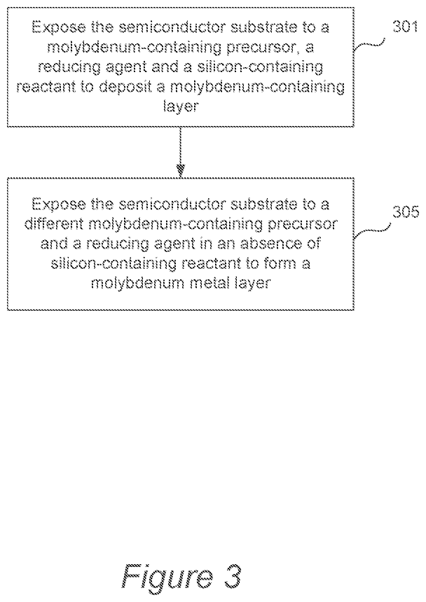

In some embodiments different molybdenum-containing precursors are used for silicon-assisted and silicon-free deposition. In one implementation, molybdenum silicide and/or molybdenum metal is first deposited using molybdenum pentachloride (MoCl₅) as a molybdenum-containing precursor in a silicon-assisted deposition, according to any of the methods provided in FIGS. 2A-2D. This is followed by depositing molybdenum metal in a silicon free deposition using a different molybdenum-containing precursor (e.g., MoO₂Cl₂). This process flow is illustrated in the process flow diagram of FIG. 3. In step 301 the substrate is exposed to a molybdenum-containing precursor, a reducing agent, and a silicon-containing reactant to deposit the molybdenum-containing layer. For example, 2-2,000 cycles of silicon-assisted deposition may be conducted. The process then follows in step 303 by exposing the substrate to a different molybdenum-containing precursor and a reducing agent in an absence of a silicon-containing reactant to deposit a layer of molybdenum metal in silicon-free deposition. For example, 2-2,000 silicon-free deposition cycles may be performed in step 303.

### Silicon-Containing Reactant

The silicon-containing reactant can serve a variety of purposes and may have different structures. In some embodiments the silicon containing reactant is assisting in the reduction of the molybdenum-containing precursor, such as it may reduce Mo(V) in a molybdenum-containing precursor to Mo(IV) or Mo(III). For example, the silicon-containing reactant can be used to reduce MoCl₅ molybdenum-containing precursor to MoCl₄ or MoCl₃, before it is fully reduced to molybdenum metal by the reducing agent. Silicon-containing reactants with Si—H and/or Si—Si bonds are particularly useful as reduction assisting reactants. In some embodiments, the silicon-containing reactant serves as a scavenger of halogen ligands that need to be removed when the molybdenum containing precursor includes molybdenum-halogen bonds. As halogen ligands are typically removed as hydrogen halides (HCl, HBr, etc.), when hydrogen is used as a reducing agent, the additional scavenging of halogens by silicon-containing precursors will assist in the halogen ligand removal. Silicon-containing precursors with Si—H and/or Si—Si bonds are suitable for this purpose. Finally, the silicon-containing reactants can be used to modify the surface of the substrate in order to modulate deposition selectivities. For example, the silicon-containing reactant may modify the surface of dielectrics (e.g., silicon-containing dielectrics) to facilitate subsequent nucleation of molybdenum on these surfaces. This may involve formation of Si—H and Si—OH bonds on the dielectric surface. Silicon-containing precursors containing Si—H bonds and Si—Si bonds can be used for surface modification purposes.

In some embodiments, silicon-containing reactant has a structure of formula (I):

SiₓR_{y}, (I)

wherein x is 1-4, y is 4-18, and each R is independently selected from the group consisting of H, a halogen, and an alkyl. In some embodiments, each R is independently selected from the group consisting of H and a halogen (e.g., F, Cl, Br or I), where halogens may be same or different.

In some embodiments the silicon-containing reactant is a silane, such as silane (SiH₄), disilane (Si₂H₆). In some embodiments the silicon-containing reactant is a halosilane, such as monochlorosilane (SiH₃Cl), dichlorosilane (SiH₂Cl₂), trichlorosilane (SiHCl₃), tetrachlorosilane (SiCl₄), hexachlorodisilane (Si₂Cl), pentachlorodisilane (Si₂HCl₅), tetrachlorodisilane (Si₂H₂Cl₄), trichlorodisilane (Si₂H₃Cl₃), dichlorodisilane (Si₂H₄Cl₂), monochloro disilane (Si₂H₅Cl), monobromosilane (SiH₃Br), dibromorosilane (SiH₂Br₂), tribromosilane (SiHBr₃), tetrabromosilane (SiBr₄), hexabromodisilane (Si₂Br₆), pentabromodisilane (Si₂HBr₅), tetrabromodisilane (Si₂H₂Br₄), tribromodisilane (Si₂H₃Br₃), dibromodisilane (Si₂H₄Br₂), and monobromodisilane (Si₂H₅Br).

In some implementations the silicon-containing reactant comprises silane, chlorosilane, dichlorosilane, trichlorosilane, tetrachlorosilane, hexachlorodisilane, pentachlorodisilane, tetrachlorodisilane, trichlorodisilane dichlorodisilane, chlorodisilane, disilane or any combination thereof.

In some embodiments the silicon-containing reactant does not include carbon atoms, because carbon-free reactants may be particularly useful for deposition of high purity molybdenum metal with low carbon content. In other embodiments, carbon atoms may be present. For example, in some embodiments, the silicon-containing reactant may include one alkyl, alkenyl, alkynyl substituents and combinations thereof.

In some embodiments, the silicon-containing reactant includes a structure of formula (II):

Si(R′)₄ (II),

wherein at least one R′ includes a carbon atom. In other embodiments, at least one R′ includes a heteroatom (e.g., nitrogen, oxygen, and/or silicon). In yet other embodiments, at least one R′ includes a carbon atom and a heteroatom (e.g., nitrogen, oxygen, and/or silicon). In particular embodiments, R′ does not include a halogen atom.

In other embodiments, the silicon-containing reactant includes a structure of formula (III):

(R′)₃Si-[L-Si(R′)₂]—R′ (III),

wherein at least one R′ includes a carbon atom and L is a linker. In some embodiments, at least one R′ includes a heteroatom (e.g., nitrogen, oxygen, and/or silicon). In yet other embodiments, at least one R′ includes a carbon atom and a heteroatom (e.g., nitrogen, oxygen, and/or silicon). In particular embodiments, R′ does not include a halogen atom.

For formula (I), non-limiting linkers for L include a covalent bond, oxy (—O—), carbonyl (—C(O)—), optionally substituted carbonimidoyl (e.g., —C(NR)—), optionally substituted imino (e.g., —NR—), an optionally substituted alkylene, optionally substituted heteroalkylene, optionally substituted arylene, and the like.

For any formula herein (e.g., for formula (I) or (II)). R¹ can be H, aliphatic, heteroaliphatic, aromatic, heteroaromatic, amino, hydrazino, azido, hydroxyl, silyl (e.g., aminosilyl, alkoxysilvl, and the like), silvloxy (e.g., aminosilyloxy, alkoxysilyloxy, and the like), cyanato (—OCN), isocyanato (—NCO), cyano (—CN), or isocyano (—NC), in which any of these may be optionally substituted.

In particular embodiments, at least one, two, three, four, or more R′ in any formula herein (e.g., for formula (II) or (III)) includes an optionally substituted aliphatic. Non-limiting aliphatic groups include alkyl, alkenyl, or alkynyl, including linear, branched, cyclic, saturated, or unsaturated forms thereof. Such groups can be unsubstituted or substituted, such as with one or more substituents described herein for alkyl. Further examples of aliphatic groups include methyl (Me), ethyl (Et), propyl (Pr), iso-propyl (iPr), cyclopropyl (cPr), butyl (Bu), sec-butyl (sBu), iso-butyl (iBu), tert-butyl (tBu), pentyl (Pe), tert-pentyl (tPe), allyl (All), vinyl (Vi), ethynyl, and the like.

In some embodiments, at least one, two, three, four, or more R¹ in any formula herein (e.g., for formula (II) or (III)) includes an optionally substituted heteroaliphatic. A heteroaliphatic group can include any including one or more carbon atoms and one or more heteroatoms (e.g., oxygen, nitrogen, and the like).

Non-limiting heteroaliphatic groups includes aliphatic-carbonyl (e.g., alkanoyl or —C(O)R^{Ak}), aliphatic-carbonyloxy (e.g., alkanoyloxy or —OC(O)R^{Ak}), aliphatic-oxy (e.g., alkoxy or —OR^{Ak}), aliphatic-oxycarbonyl (e.g., alkoxycarbonyl or —C(O)OR^{Ak}), amino (e.g., —NR^{N1}R^{N2}), aromatic-carbonyl (e.g., aryloyl or —C(O)R^{Ar}), aromatic-carbonyloxy (e.g., aryloyloxy or —OC(O)R^{Ar}), aromatic-oxy (e.g., aryloxy or —OR^{Ar}), aromatic-oxycarbonyl (e.g., aryloxycarbonyl or —C(O)OR^{Ar}), imidoyl (e.g., —C(NR^{N1})H, —C(NR^{N1})R^{Ak}, or —C(NR^{N1})R^{Ar}), carbamoyl (e.g., —C(O)NR^{N1}R^{N2}), carbamoyloxy (e.g., —OC(O)NR^{N1}R^{N2}), carboxyl (—CO₂H), formyl (—C(O)H), heteroaromatic, heterocyclyl (e.g., optionally substituted furanyl, tetrahydrofuranyl, pyrrolidinyl, pyrrolyl, imidazolyl, pyrazolyl, triazolyl, piperidinyl, pyridinyl, pyrimidinyl, pyridazinyl, pyrazinyl, oxazolyl, morpholinyl, and the like), hydrazino (e.g., —NR^{N1}—NR^{N2}R^{N3}), silyl (e.g., —SiR^{S1}R^{S2}R^{S3}), and silyloxy (e.g., —O—SiR^{S1}R^{S2}R^{S3}). Each of these groups can be optionally substituted with any substituent described herein (e.g., as described herein for alkyl). Heteroaliphatic groups can include linear, branched, cyclic (e.g., heterocyclyl), saturated, or unsaturated forms thereof.

Heteroaliphatic groups can include R^{Ak} and/or R^{Ar} moieties. In some embodiments, R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl. In other embodiments, R^{Ar} is optionally substituted aromatic, optionally substituted heteroaromatic, optionally substituted aryl, or optionally substituted heteroaryl.

Nitrogen-containing groups (e.g., amino, imidoyl, etc.) can include R^{N1}, R^{N2}, and/or R^{N3} moieties attached to a nitrogen atom. In some embodiments, each of R^{N1}, R^{N2}, and R^{N3} is, independently, H, optionally substituted aliphatic, optionally substituted heteroaliphatic, optionally substituted aromatic, optionally substituted heteroaromatic, optionally substituted silyl, or optionally substituted silyloxy. In particular embodiments, R^{N1} and R^{N2} or R^{N2} and R^{N3} can be taken together, with the nitrogen atom to which each is attached, to form an optionally substituted heterocyclyl. Such nitrogen-containing groups can be included within other moieties, such as within silyl or silyloxy groups.

Silicon-containing groups (e.g., silyl, etc.) can include R^{S1}, R^{S2}, and/or R^{S3} attached to a silicon atom. In some embodiments, each of R^{S1}, R^{S2}, and R^{S3} is, independently, H, optionally substituted aliphatic, optionally substituted heteroaliphatic, optionally substituted aromatic, optionally substituted heteroaromatic, or optionally substituted amino. Such silicon-containing groups can be included within other moieties, such as within amino groups.

In some embodiments, the silyl group is an alkylsilyl group having one or more aliphatic groups attached to the silicon atom. In one instance, the alkylsilyl group is —Si(R)ₐ(R^{Ak})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; a≥0; b≥1; and a+b=3. Yet other non-limiting alkylsilyl groups include —SiH₂R^{Ak}, —SiH[R^{Ak}]₂, or —Si[R^{Ak}]₃, in which R^{Ak} is any provided herein.

In some embodiments, the silyl group is an alkoxysilyl group having one or more aliphatic groups attached to the silicon atom by way of an oxy (—O—) group. In one instance, the alkoxylsilyl group is —Si(R)ₐ(OR^{Ak})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; a≥0; b≥1; and a+b=3. Yet other non-limiting alkoxysilvl groups include —SiH₂[OR^{Ak}], —SiH[OR^{Ak}]₂, or —Si[OR^{Ak}]₃, in which R^{Ak} is any described herein.

In other embodiments, the silyl group is an arylsilyl group having one or more aromatic groups attached to the silicon atom. In one instance, the arylsilyl group is —Si(R)ₐ(R^{Ar})_{b}, in which R is, independently, H, aliphatic, heteroaliphatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ar} is optionally substituted aromatic, optionally substituted heteroaromatic, optionally substituted aryl, or optionally substituted heteroaryl; a≥0; b≥1; and a+b=3. Yet other non-limiting arylsilyl groups include —SiH₂R^{Ar}, —SiH[R^{Ar}]₂, or —Si[R^{Ar}]₃, in which R^{Ar} is any described herein.

In yet other embodiments, the silyl group is an aryloxysilyl group having one or more aromatic groups attached to the silicon atom by way of an oxy (—O—) group. In one instance, the arylsilyl group is —Si(R)ₐ(OR^{Ar})_{b}, in which R is, independently, H, aliphatic, heteroaliphatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ar} is optionally substituted aromatic, optionally substituted heteroaromatic, optionally substituted aryl, or optionally substituted heteroaryl, a≥0; b≥1; and a+b=3. Yet other non-limiting aryloxysilyl groups include —SiH₂[OR^{Ar}], —SiH[OR^{Ar}]₂, or —Si[OR^{Ar}]₃, in which R^{Ar} is any described herein.

A silyl group can also include an aminosilyl having one or more optionally substituted amino groups attached to the silicon atom. In one instance, the aminosilyl group is —Si(R)ₐ(NR^{N1}R^{N2})_{b}, in which R is, independently, H, aliphatic, heteroaliphatic, aromatic, heteroaromatic, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; a≥0; b≥1; and a+b=3. Yet other non-limiting embodiments of aminosilyl groups include —SiH₂[NR^{N1}R^{N2}], —SiH[R^{Ak}][NR^{N1}R^{N2}], —Si[R^{Ak}]₂[NR^{N1}R^{N2}], —SiH[NR^{N1}R^{N2}]₂, —Si[R^{Ak}][NR^{N1}R^{N2}]₂, or —Si[NR^{N1}R^{N2}]₃), such as —SiH₂[NH₂], —SiHR^{Ak}[NH₂], —Si[R^{Ak}]₂[NH₂], —SiH₂[NH(R^{Ak})], —SiHR^{Ak}[NH(R^{Ak})], —Si[R^{Ak}]₂[NH(R^{Ak})], —SiH₂[N(R^{Ak})₂], —SiHR^{Ak}[N(R^{Ak})₂], —Si[R^{Ak}]₂[N(R^{Ak})₂], —SiH[NH₂]₂, —SiR^{Ak}[NH₂]₂, —SiH[NH(R^{Ak})]₂, —SiR^{Ak}[NH(R^{Ak})]₂, —Si[NH(R^{Ak})₂NH₂], —SiR^{Ak}[NH(R^{Ak})][NH₂], —SiH[N(R^{Ak})₂]₂, —SiR^{Ak}[N(R^{Ak})₂]₂, —SiH[N(R^{Ak})₂][NH₂], —SiR^{Ak}[N(R^{Ak})₂][NH₂], —Si[NH₂]₃, —Si[N(R^{Ak})₂][NH₂]₂, —Si[N(R^{Ak})₂]₂[NH₂], —Si[N(R^{Ak})₂]₃, —Si[NH(R^{Ak})][NH₂]₂, —Si[NH(R^{Ak})₂]₂[NH₂], —Si[NH(R^{Ak})]₃, —Si[NH(R^{Ak})][N(R¹)₂]₂, —Si[NH(R^{Ak})]₂[N(R^{Ak})₂], and the like, in which R^{Ak} is optionally substituted aliphatic, heteroaliphatic, alkyl, alkenyl, alkynyl, or alkoxy; and each of R^{N1} and R^{N2} is any described herein.

In some embodiments, the silyl group is —Si(R′)ₐ(OR)_{b}(NR₂)_{c}, in which each R¹ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

In other embodiments, any of the silyl groups herein can be attached to the parent compound through an oxy bond. In some embodiments, the silyloxy group is —O—Si(R′)ₐ(OR)_{b}(NR₂)_{c}, in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl. Yet other non-limiting silyloxy groups include —O—Si(R)ₐ(R^{Ak})_{b}, —O—Si(R)ₐ(OR^{Ak})_{b}, —O—Si(R)ₐ(R^{Ar})_{b}, —O—Si(R)(OR^{Ar})_{b}, —O—Si(R)(NR^{N1}R^{N2})_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic, optionally substituted heteroaliphatic, optionally substituted alkyl, optionally substituted alkenyl, optionally substituted alkynyl, optionally substituted cycloalkyl, optionally substituted heteroalkyl, optionally substituted heteroalkenyl, optionally substituted heteroalkynyl, or optionally substituted heterocyclyl; R^{Ar} is optionally substituted aromatic, optionally substituted heteroaromatic, optionally substituted aryl, or optionally substituted heteroaryl; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; a≥0; b≥1; and a+b=3. Yet other non-limiting silyloxy groups include alkylsilyloxy (e.g., —O—SiH₂R^{Ak}, —O—SiH[R^{Ak}]₂, or —O—Si[R^{Ak}]₃); alkoxysilyloxy (e.g., —O—SiH₂[OR^{Ak}]—O—SiH[OR^{Ak}]₂, or —O—Si[OR^{Ak}]₃); arylsilyloxy (e.g., —O—SiH₂R^{Ar}, —O—SiH[R^{Ar}]₂, or —O—Si[R^{Ar}]₃); or aryloxysilyloxy (e.g., —O—SiH₂[OR^{Ar}], —O—SiH[OR^{Ar}]₂, or —O—Si[OR^{Ar}]₃). In some embodiments, the silyl group is aminosilyloxy (e.g., —O—SiH₂[NR^{N1}R^{N2}], —O—SiH[R^{Ak}][NR^{N1}R^{N2}], —O—Si[R^{Ak}]₂[NR^{N1}R^{N2}], —O—SiH[NR^{N1}R^{N2}]₂, —O—Si[R^{Ak}][NR^{N1}R^{N2}]₂, or —O—Si[NR^{N1}R^{N2}]₃).

Silyl and silyloxy group can have a mixed combination of aliphatic and aromatic groups. In one instance, the silyl group is —Si(R)ₐ(R^{Ak})_{b}(R^{Ar}), or —Si(R)ₐ(OR^{Ak})_{b}(OR^{Ak})_{c}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; R^{Ak} is optionally substituted aliphatic (e.g., optionally substituted alkyl) or optionally substituted heteroaliphatic (e.g., optionally substituted alkoxy or optionally substituted amino); R^{Ar} is optionally substituted aromatic or optionally substituted heteroaromatic; each of a, b, and c≥0; and a+b+c=3.

In another instance, the silyl group is —Si(R)ₐ(NR^{Ak}₂)_{b}, —Si(R)ₐ(NR^{Ak}R^{Ar})_{b}, or —Si(R)ₐ(NR^{Ar}₂)_{b}, in which R is, independently, H, aromatic, heteroaromatic, amino, hydrazino, azido, hydroxyl, silyl (e.g., aminosilyl, alkoxysilyl, and the like), silyloxy (e.g., aminosilyloxy, alkoxysilyloxy, and the like), cyanato, isocyanato, cyano, or isocyano, in which any of these may be optionally substituted; each of R^{N1} and R^{N2} is, independently, H, optionally substituted aliphatic, optionally substituted heteroaliphatic, optionally substituted aromatic, optionally substituted heteroaromatic, optionally substituted silyl, or optionally substituted silyloxy, in which R^{N1} and R^{N2} can be taken together, with the nitrogen atom to which each is attached, to form an optionally substituted heterocyclyl; each of a and b≥0; and a+b=3.

In yet another instance, the silyloxy group is —O—Si(R)ₐ(R^{Ak})_{b}(R^{Ar})_{c}, —O—Si(R)ₐ(OR^{Ak})_{b}(OR^{Ar})_{c}, —O—Si(R)ₐ(NR^{Ak}₂)_{b}, —O—Si(R)ₐ(NR^{Ak}R^{Ar})_{b}, or —O—Si(R)ₐ(NR^{Ar}₂)_{b}, in which R, R^{Ak}, and R^{Ar} are any described herein, and a, b, and c are any described herein.

In some embodiments, at least one, two, three, four, or more R′ in any formula herein (e.g., for formula (I) or (II)) includes an optionally substituted aliphatic-oxy, heteroaliphatic-oxy, aromatic-oxy, or heteroaromatic-oxy. For instance, R′ can be —O—R, in which R is optionally substituted aliphatic (e.g., alkyl, alkenyl, alkynyl, cycloalkyl, cycloalkenyl, or cycloalkynyl), optionally substituted heteroaliphatic (e.g., heteroalkyl, heteroalkenyl, heteroalkynyl, or heterocyclyl), optionally substituted aromatic (e.g., aryl), optionally substituted heteroaromatic (e.g., heteroaryl), optionally substituted aliphatic-carbonyl (e.g., alkanoyl or —C(O)R^{Ak}, in which R^{Ak} is optionally substituted aliphatic or any described herein), optionally substituted silyl (e.g., —SiR^{S1}R^{S2}R^{S3} or —Si(R′)ₐ(OR)_{b}(NR₂)_{c}, including any described herein), or optionally substituted amino (e.g., —NR^{N1}R^{N2}, including any described herein).

In particular embodiments, at least one, two, three, four, or more R′ in any formula herein (e.g., for formula (I) or (II)) includes an optionally substituted aromatic or optionally substituted heteroaromatic. Non-limiting aromatic and heteroaromatic groups include phenyl, benzyl, naphthyl, furanyl, pyrrolyl, imidazolyl, pyrazolyl, triazolyl, pyridinyl, pyrimidinyl, pyridazinyl, pyrazinyl, oxazolyl, and the like.

In particular embodiments, at least one, two, three, four, or more R′ in any formula herein (e.g., for formula (I) or (II)) includes an optionally substituted amino (e.g., —NH₂, —NR^{N1}H, or —NR^{N1}R^{N2}). In particular embodiments, each of R^{N1} and R^{N2} is, independently, H, optionally substituted aliphatic, optionally substituted heteroaliphatic, optionally substituted aromatic, optionally substituted heteroaromatic, optionally substituted amino, hydroxyl, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R^{N1} and R^{N2} can be taken together, with the nitrogen atom to which each is attached, to form an optionally substituted heterocyclyl.

Non-limiting instances of R^{N1} and R^{N2} can include H, aliphatic, alkyl (e.g., —R^{Ak}), alkenyl, alkynyl, aliphatic carbonyl (e.g., alkanoyl or —C(O)R^{Ak}), aliphatic-carbonyloxy (e.g., alkanoyloxy or —OC(O)R^{Ak}), aliphatic-oxy (e.g., alkoxy or —OR^{Ak}), aliphatic-oxycarbonyl (e.g., alkoxycarbonyl or —C(O)OR^{Ak}), amino (e.g., —NR₂, in which each R is, e.g., H, optionally substituted aliphatic, optionally substituted heteroaliphatic, optionally substituted aromatic, or optionally substituted heteroaromatic), aromatic (e.g., aryl or —R^{Ar}), aromatic-carbonyl (e.g., aryloyl or —C(O)R^{Ar}), aromatic-carbonyloxy (e.g., aryloyloxy or —OC(O)R^{Ar}), aromatic-oxy (e.g., aryloxy or —OR^{Ar}), aromatic-oxycarbonyl (e.g., aryloxycarbonyl or —C(O)OR^{Ar}), imidoyl (e.g., —C(NR)H, —C(NR)R^{Ak}, or —C(NR)R^{Ar}, in which each R is, e.g., H, optionally substituted aliphatic, optionally substituted heteroaliphatic, optionally substituted aromatic, or optionally substituted heteroaromatic), carbamoyl (e.g., —C(O)NR₂, in which each R is, e.g., H, optionally substituted aliphatic, optionally substituted heteroaliphatic, optionally substituted aromatic, or optionally substituted heteroaromatic), carbamoyloxy (e.g., —OC(O)NR₂, in which each R is, e.g., H, optionally substituted aliphatic, optionally substituted heteroaliphatic, optionally substituted aromatic, or optionally substituted heteroaromatic), carboxyl (—CO₂H), formyl (—C(O)H), heteroaromatic, heterocyclyl (e.g., optionally substituted furanyl, tetrahydrofuranyl, pyrrolidinyl, pyrrolyl, imidazolyl, pyrazolyl, triazolyl, piperidinyl, pyridinyl, pyrimidinyl, pyridazinyl, pyrazinyl, oxazolyl, morpholinyl, and the like), hydroxyl (—OH), silyl (e.g., —SiR^{S1}R^{S2}R^{S3} or —Si(R¹)ₐ(OR)O(NR₂)_{c}), and silyloxy (e.g., —O—SiR^{S1}R^{S2}R^{S3} or —O—Si(R¹)ₐ(OR)_{b}(NR₂)_{c}). For any of these groups, where indicated, R^{Ak}, R^{Ar}, R′, R, R^{S1}, R^{S2}, R^{S3}, a, b, and c can be any described herein.

Yet other non-limiting amino groups include —NH₂, —NHMe, —NMe₂, —NHEt, —NMeEt, —NEt, —NHnPr, —NMenPr, —NnPr₂, —NHiPr, —NMeiPr, —NiPr₂, —NHsBu, —NMesBu, —NsBu₂, —NHtBu, —NMetBu, —NtBu₂, —N[SiH₃]₂, —N[Si(Me)₃]₂, —N[Si(Et)₃]₂, —NH[SiH₃], —NH[Si(Me)₃], —NH[Si(Et)₃], —NMe[SiH₃], —NMe[Si(Me)₃], —NMe[Si(Et)₃], —N[SiH₂Me]₂, —N[SiHMe₂]₂, —N[SiH₂Et]₂, —N[SiHEt₂]₂, —N[SiHMeEt]₂, —NH[SiH₂Me], —NH[SiHMe₂], —NH[SiH₂Et], —NH[SiHEt₂]₂, —NH[SiHMeEt], —NMe[SiH₂Me], —NMe[SiHMe₂], —NMe[SiH₂Et], —NMe[SiHEt₂]₂, —NMe[SiHMeEt], and the like.

In particular embodiments, at least one, two, three, four, or more R¹ in any formula herein (e.g., for formula (II) or (III)) includes an optionally substituted hydrazino (e.g., —NH—NH₂ or —NR^{N1}—NR^{N2}R^{N3}). In particular embodiments, each of R^{N1}, R^{N2}, and R^{N3} is, independently, H, optionally substituted aliphatic, optionally substituted heteroaliphatic, optionally substituted aromatic, optionally substituted heteroaromatic, optionally substituted amino, hydroxyl, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R^{N1} and R^{N2} or R^{N2} and R^{N3} can be taken together, with the nitrogen atom to which each is attached, to form an optionally substituted heterocyclyl. Yet other non-limiting hydrazino groups include —NH—NH₂, —NMe-NH₂, —NH—NHMe, —NH—NMe₂, —NMe-NMe₂, —NEt-NH₂, —NH—NHEt, —NH—NEt₂, —NMe-NEt₂, and the like.

In some embodiments, at least one, two, three, four, or more R′ in any formula herein (e.g., for formula (II) or (III)) includes an optionally substituted silyl. In one embodiment, silyl is —SiR^{S1}R^{S2}R^{S3}, in which each of R^{S1}, R^{S2}, and R^{S3} is, independently, H, optionally substituted aliphatic, optionally substituted heteroaliphatic, optionally substituted aromatic, optionally substituted heteroaromatic, optionally substituted amino, optionally substituted hydrazino, azido, hydroxyl, optionally substituted silyl, optionally substituted silyloxy, optionally substituted alkyl, optionally substituted alkenyl, optionally substituted alkynyl, optionally substituted alkoxy, optionally substituted heteroalkyl, optionally substituted heteroalkenyl, optionally substituted heteroalkynyl, optionally substituted heterocyclyl, optionally substituted aryl, optionally substituted aryloxy, cyanato, isocyanato, cyano, isocyano, and the like. Non-limiting silyl groups include any described herein, such as —Si(R)ₐ(R^{Ak})_{b}, —Si(R)ₐ(OR^{Ak})_{b}, —Si(R)ₐ(R^{Ar})_{b}, —Si(R)ₐ(OR^{Ar})_{b}, —Si(R)ₐ(NR^{N1}R^{N2})_{b}, —Si(R′)ₐ(OR)_{b}(NR₂), and the like. Yet other non-limiting silyl groups include —SiH₃, —SiH₂Me, —SiHMe₂, —SiMe₃, —Si(OH)₃, —SiH₂(OMe), —SiH(OMe)₂, —Si(OMe)₃, —SiH₂(NH₂), —SiHMe(NH₂), —SiMe₂(NH₂), —SiH(NH₂)₂, —SiMe(NH₂)₂, —Si(NH₂)₃, —SiH₂(NMe₂), —SiH₂(NMe₂), —SiHMe(NMe₂), —Si(Me)₂(NMe₂)₂, —SiMe(NMe₂)₂, —Si(NMe₂)₃, —SiH₂(NHMe), —SiHMe(NHMe), —SiH(NHMe)₂, —SiMe(NHMe)₂, —Si(NHMe)₃, and the like.

In other embodiments, at least one, two, three, four, or more R¹ in any formula herein (e.g., for formula (II) or (III)) includes an optionally substituted silyloxy. Non-limiting silyloxy groups include any described herein, such as —O—Si(R)ₐ(R^{Ak})_{b}, —O—Si(R)ₐ(OR^{Ak})_{b}, —O—Si(R)ₐ(R^{Ar})_{b}, —O—Si(R)ₐ(OR^{Ar})_{b}, —O—Si(R)ₐ(NR^{N1}R^{N2})_{b}, —O—Si(R¹)ₐ(OR)_{b}(NR₂)_{c}, and the like. Yet other non-limiting silyloxy groups include —O—SiH₃, —O—SiH₂Me, —O—SiHMe₂, —O—SiMe₃, —O—Si(OH)₃, —O—SiH₂(OMe), —O—SiH(OMe)₂, —O—Si(OMe)₃, —O—SiH₂(NH₂), —O—SiHMe(NH₂), —O—SiMe₂(NH₂), —O—SiH(NH₂)₂, —O—SiMe(NH₂)₂, —O—Si(NH₂)₃, —O—SiH₂(NMe₂), —O—SiH₂(NMe₂), —O—SiHMe(NMe₂), —O—Si(Me)₂(NMe₂)₂, —O—SiMe(NMe₂)₂, —O—Si(NMe₂)₃, —O—SiH₂(NHMe), —O—SiHMe(NHMe), —O—SiH(NHMe)₂, —O—SiMe(NHMe)₂, —O—Si(NHMe)₃, and the like.

In yet other embodiments, at least one, two, three, four, or more R¹ in any formula herein (e.g., for formula (II) or (III)) includes azido (—N₃), hydroxyl (—OH), cyanato (—OCN), isocyanato (—NCO), cyano (—CN), and/or isocyano (—NC).

The organic silicon-containing precursor may be selected from the group consisting of silane, disilane, trisilane, tetrasilane, amine-substituted versions of any of the foregoing silanes, and trisilylamine.

Examples of inorganic silicon-containing reactants include, but are not limited to, silanes, polysilanes, halosilanes, and aminosilanes. A silane contains hydrogen and/or carbon groups, but does not contain a halogen. A polysilane may have the formula (H₃Si—(SiH₂)ₙ—SiH₃), where n≥1. Examples of silanes include silane (SiH₄), disilane (Si₂H₆), trisilane, tetrasilane and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, tetra-ethyl-ortho-silicate (also known as tetra-ethoxy-silane or TEOS) and the like.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamido)silane (DIPAS), bis(diethylamino)silane (BDEAS), and the like. A further example of an aminosilane is trisilylamine (N(SiH₃)₃).

Examples of silicon-containing reactants include siloxanes, alkyl silane or hydrocarbon-substituted silane, or a nitrogen-containing carbon-containing reactant. Examples of siloxanes include 2,4,6,8-tetramethylcyclotetrasiloxane (TMCTS), heptamethylcyclotetrasiloxane (HMCTS), silsesquioxane, disiloxanes, such as pentamethyldisiloxane (PMDSO) or tetramethyldisiloxane (TMDSO), and trisiloxanes such as hexamethyltrisiloxane or heptamethyltrisiloxane. Alkyl silanes include a central silicon atom with one or more alkyl groups bonded to it as well as one or more hydrogen atoms bonded to it. In some embodiments, any one or more of the alkyl groups contain 1-5 carbon atoms. The hydrocarbon groups may be saturated or unsaturated (e.g., alkene (e.g., vinyl), alkyne, and aromatic groups). Examples include but are not limited to trimethylsilane (3MS), triethylsilane, pentamethyl disilamethane ((CH₃)₂Si—CH₂—Si(CH₃)₃), and dimethylsilane (2MS). Additionally, disilanes, trisilanes, or other higher silanes may be used in place of monosilanes. In some embodiments, one of the silicon atoms can have a carbon-containing or hydrocarbon group attached to it, and one of the silicon atoms can have a hydrogen atom attached to it. Example carbon-containing reactants including a nitrogen include methyl-substituted disilazanes and trisilazanes, such as tetramethyldisilazane and hexamethyl trisilazane.

Yet other examples of organic silicon-containing reactants can include siloxanes such as cyclotetrasiloxanes such as heptamethylcyclotetrasiloxane (HMCTS) and tetramethylcyclotetrasiloxane. Other cyclic siloxanes can also include but are not limited to cyclotrisiloxanes and cyclopentasiloxanes. Other examples of suitable precursors include linear siloxanes such as, but not limited to, disiloxanes, such as pentamethyldisiloxane (PMDSO), tetramethyldisiloxane (TMDSO), hexamethyl trisiloxane, and heptamethyl trisiloxane. For undoped silicon carbide, examples of suitable precursors include monosilanes substituted with one or more alkyl, alkene, and/or alkyne groups containing, e.g., 1-5 carbon atoms. Examples include but are not limited to trimethylsilane (3MS), dimethylsilane (2MS), triethylsilane (TES), and pentamethyldisilamethane. Additionally, disilanes, trisilanes, or other higher silanes may be used in place of monosilanes. An example of one such disilane from the alkyl silane class is hexamethyldisilane (HMDS). Another example of a disilane from the alkyl silane class can include pentamethyldisilane (PMDS). Other types of alkyl silanes can include alkylcarbosilanes, which can have a branched polymeric structure with a carbon bonded to a silicon atom as well as alkyl groups bonded to a silicon atom. Examples include dimethyl trimethylsilyl methane (DTMSM) and bis-dimethylsilyl ethane (BDMSE). Examples of other suitable precursors include, e.g., alkyldisilazanes and possibly compounds including amino (—NH₂) and alkyl groups separately bonded to one or more silicon atoms. Alkyldisilazanes include silizanes and alkyl groups bonded to two silicon atoms. An example includes 1,1,3,3-tetramethyldisilazane (TMDSN).

In the Si-containing reactants described herein, different kinds of R¹ can be attached to the silicon atom. Further Si-containing precursors are described herein.

### Aminosilanes

A silicon-containing reactant can include one or more optionally substituted amino groups, thereby providing a non-limiting amino silane. In one embodiment, the precursor has a formula of (R′)₄₋ₓSi(NR″₂)ᵣ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₐ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynl.

The silicon-containing reactant can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)Si(NR″₂), wherein R′ and R″ can be any described herein.

The silicon-containing reactant can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The silicon-containing reactant can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The silicon-containing reactant can include a heterocyclyl group having a nitrogen atom. In one embodiment, the formula has a formula of H₃Si—Het, in which Het is an optionally substituted heterocyclyl including at least one nitrogen atom. In particular embodiments, the precursor has a formula of

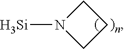

in which the heterocyclyl group can be optionally substituted (e.g., with any substituent described herein as a substitution for alkyl), and wherein n is 1, 2, 3, 4, or 5. In one embodiment, the formula has a formula of R′₃Si—Het, in which Het is an optionally substituted heterocyclyl including at least one nitrogen atom, and each R′ can independently be any described herein. In particular embodiments, the precursor has a formula of

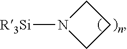

in which the heterocyclyl group can be optionally substituted (e.g., with any substituent described herein as a substitution for alkyl); each R′ can independently be any described herein; and wherein n is 1, 2, 3, 4, or 5.

In some instances, the silicon-containing reactant can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the silicon-containing reactant has a formula of (R″₂N)(R′)₂Si—Si(R′)₂(NR″₂), wherein R′ and R″ can be any described herein. In another embodiment, the silicon-containing reactant has a formula of (R″₂N)₂(R′)Si—Si(R′)(NR″₂)₂, wherein R′ and R″ can be any described herein. In yet another embodiment, the silicon-containing reactant has a formula of (R″₂N)₃Si—Si(NR″₂)₃, wherein each R″ can independently be any described herein.

The silicon-containing reactant can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the silicon-containing reactant has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the silicon-containing reactant has a formula of (R″₂N)ₓ(H)₃₋ₓSi—NR—Si(H)₃₋ₓ(NR″₂)ₓ, wherein R, R′, and R″ can be any described herein.

The silicon-containing reactant can include a combination of R′ groups with a linker having a heteroatom. In one instance, the silicon-containing reactant has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The silicon-containing reactant can include any useful combination of R′ and NR₂ groups in combination with two silicon atoms. In one instance, the precursor has a formula of (R″2N)(R′)₂Si-L-Si(R′)₂(NR″₂)ₓ, wherein L, R′, and R″ can be any described herein.

The silicon-containing reactant can include heterocyclic groups including the silicon and nitrogen atoms. In one embodiment, the precursor has a formula of

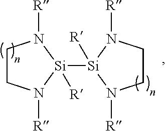

wherein R′ and R″ can be any described herein, and wherein n is 1, 2, 3, or 4.

In another embodiment, the silicon-containing reactant has a formula of

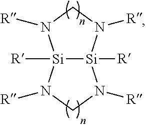

wherein R′ and R″ can be any described herein, and wherein n is 1, 2, 3, or 4. In yet another embodiment, the precursor has a formula of

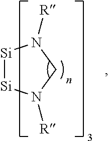

in which each R″ can independently be any described herein; and wherein n is 1, 2, 3, or 4.

In another embodiment, the silicon-containing reactant has a formula of

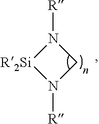

wherein R′ and R″ can be any described herein, and wherein n is 1, 2, 3, or 4. In yet another embodiment, the silicon-containing reactant has a formula of

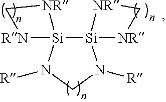

wherein R″ can independently be any described herein, and wherein n is 1, 2, 3, or 4.

In any silicon-containing reactant herein, two R″ can be taken together, with the nitrogen atom to which each is attached, to form an optionally substituted heterocyclyl.

Silicon-containing reactants can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak}₂)₂, (R^{Ak})(H)Si(NR^{Ak}₂)₂, HSi(NH₂)(NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of silicon-containing reactant include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt₃[NEt₂]); isopropylaminodimethylsilane (SiHMe₂[NHiPr]); isopropylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylamino triethylsilane (SiEt₃[NiPr₂]); n-propylaminotnmethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMes[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropyl aminosilane (SiH₃[NiPmPr]); N-methylcyclohexylaminosilane (SiH₃[NMeCy]); N-ethyl cyclohexylaminosilane (SiH₃[NEtCy]); allylphenylaminosilane (SiH₃[NAllPh]); N-isopropyl cyclohexylaninosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolidinyl); piperidinotrimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidaolyl); bis(dimethylamino)silane (SiH₂[NMe₂]₂ or BDMAS); bis(dimethylamino) methylsilane (SiMeH[NMe]₂); bis(dimethylamino)dimethylsilane (SiMe₂[NMe₂]₂ or BDMADMS); bis(dimethylamino)diethylsilane (SiEt₂[NMe₂]₂); bis(dimethylamino) methylvinylsilane (SiMeVi[NMe₂]₂); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino)diethylsilane (SiEt₂[NMeEt]₂); bis(ethylmethylamino) methylvinylsilane (SiMeVi[NMeEt]₂); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino)diethylsilane (SiEt₂[NEt₂]₂); bis(iso-propylamino) dimethylsilane (SiMe₂[NHiPr]₂); bis(iso-propylamino)diethylsilane (SiEt₂[NHiPr]₂); bis(iso-propylamino)methylvinylsilane (SiMeVi[NHiPr]₂); bis(di-iso-propylamino)silane (SiH₂[NiPr₂]₂); bis(di-iso-propylamino)dimethylsilane (SiMe₂[NiPr₂]₂); bis(di-iso-propylamino) diethylsilane (SiEt₂[NiPr₂]₂); bis(di-iso-propylamino)methylvinylsilane (SiMeVi[NiPr₂]₂); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]₃ or 3DMAS); tris(dimethylamino)phenylsilane (SiPh[NMe₂]₃); tris(dimethylamino) methylsilane (SiMe[NMe₂]₃); tris(dimethylamino)ethylsilane (SiEt[(NMe₂]₃); tris(ethylmethylamino)silane (SiH[NEtMe]₃); tris(diethylamino)silane (SiH[NEt₂]₃); tris(iso-propylamino)silane (SiH[NHiPr]₃, C₉H₂₁N₃Si, or TIPAS); tris(dimethylamino)silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino) disilane ([Et₂N]₂EtSi—SiEt[NEt₂]₂); 1,2-dimethyl-tetrakis(dimethylamino)disilane ([Me₂N]₂MeSi—SiMe[NMe₂]₂); 1,2-dimethyl-tetrakis(diethylamino)disilane ([EtN]₂MeSi—SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

### Isocyanato Silanes

A silicon-containing reactant can include one or more isocyanato groups, thereby providing a non-limiting isocyanato silane. In one embodiment, the silicon-containing reactant has a formula of (R′)₄₋ₓSi(NCO)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyan, or isocyano, in which any of these may be optionally substituted.

In another embodiment, the silicon-containing reactant has a formula of (R′)_{z}Si(NCO)ₓ(NR″₂)_{y}, wherein:
x is 1, 2, 3, or 4;
each of y and z is, independently, 0, 1, 2, or 3;
x+y+z=4;
each R′ is, independently, H, aliphatic, aliphatic-carbonyl, aliphatic-carbonyloxy,
aliphatic-oxy, aliphatic-oxycarbonyl, heteroaliphatic, heteroaliphatic-carbonyl,
heteroaliphatic-carbonyloxy, heteroaliphatic-oxy, heteroaliphatic-oxycarbonyl, aromatic,
aromatic-carbonyl, aromatic-carbonyloxy, aromatic-oxy, aromatic-oxycarbonyl,
heteroaromatic, heteroaromatic-oxy, amino, hydrazino, azido, hydroxyl, silyl, silyloxy,
cyanato, isocyanato, cyano, or isocyano, in which any of these may be optionally substituted; and
each R″ is, independently, H, aliphatic, heteroaliphatic, aromatic, heteroaromatic, or
amino, in which any of these may be optionally substituted; or optionally in which two R″ can be taken together, with the nitrogen atom to which each is attached, to form an optionally substituted heterocyclyl.

In yet another embodiment, the silicon-containing reactant has a formula of (NCO)ₓ(R′)₃₋ₓSi-L-Si(R′)₃₋ₓ(NCO)ₓ, wherein:
each x is, independently, 0, 1, 2, or 3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl, and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In some embodiments, R′ is H, optionally substituted amino (e.g., —NR—), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1, and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted, each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

Silicon-containing reactants can include any of the following, e.g., (R′)Si(NCO)(NR″₂)₂, (R′)₂Si(NCO)(NR″₂), (R′)₂Si(NCO)(N[SiR₃]₂), or tetraisocyanatosilane (Si[NCO]₄). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R is, independently, H, optionally substituted aliphatic, optionally substituted heteroaliphatic, optionally substituted alkyl, optionally substituted alkenyl, optionally substituted alkynyl, optionally substituted alkoxy, optionally substituted aromatic, optionally substituted heteroaromatic, optionally substituted aryl, or optionally substituted heteroaryl.

### Azido Silanes

A silicon-containing reactant can include one or more azido groups, thereby providing a non-limiting azido silane. In one embodiment, the precursor has a formula of

(R′)₄₋ₓSi(N₃)ₓ, wherein:
x is 1, 2, 3, or 4; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In another embodiment, the silicon-containing reactant has a formula of (R′)ₓSi(N₃)ₓ(NR″₂)_{y}, wherein:
x is 1, 2, 3, or 4;
each of y and z is, independently, 0, 1, 2, or 3;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the silicon-containing reactant has a formula of (N₃)ₓ(R′)₃₋ₓSi-L-Si(R′)₃₋ₓ(N₃)ₓ, wherein:
each x is, independently, 0, 1, 2, or 3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl; and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R)ₐ(NR₂)_{b}, —Si(R)ₐ(NR₂)_{b}, —Si(R)ₐ(OR)_{b}(NR₂)_{c}, —Si(R)ₐ(OR)_{b}(NR₂)_{c}, —O—SiR′₃, —O—SiR₃, —O—Si(R)ₐ(OR)_{b}, —O—Si(R)ₐ(OR)_{b}, —O—Si(R)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

Silicon-containing reactants can include any of the following, e.g., (R′)₃Si(N₃), (R′)₂Si(N₃)₂, (R′)Si(N₃)₃, or Si(N₃)(NR″₂)₃. In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). Non-limiting examples of precursors also include tris(dimethylamino)silylazide ([Me₂N]₃SiN₃); di-tert-butyl diazidosilane (tBu₂Si(N₃)₂); ethylsilicon triazide (EtSi(N₃)₃); and the like.

### Hydrazino Silanes

A silicon-containing reactant can include one or more optionally substituted hydrazino groups, thereby providing a non-limiting hydrazino silane. In one embodiment, the precursor has a formula of (R′)₄₋ₓSi(NR″—NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (NR″₂—NR″)(R′)₃₋ₓSi-L-Si(R′)₃₋ₓ(NR″—NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In yet another embodiment, the precursor has a formula of (R′)₄₋ₓSi(NR″-L-NR″₂)ₓ, wherein: x is 1, 2, 3, or 4; and each L, R′, and R″ can be any described herein.

In particular embodiments, L is optionally substituted imino, such as —NR—, in which R is H, optionally substituted aliphatic, optionally substituted allyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic. In yet other embodiments, L is —NR—NR—, in which R is any described herein (e.g., R is H, optionally substituted aliphatic, optionally substituted alkyl, optionally substituted alkenyl, optionally substituted alkynyl, or optionally substituted aromatic).

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

The silicon-containing reactant can include any useful combination of R′ and hydrazino groups. In one embodiment, the precursor has a formula of (R′)₃Si(NR″-L-NR″₂) or (R′)₃Si(NR″—NR″₂), wherein L, R′, and R″ can be any described herein.

The silicon-containing reactant can include a plurality of hydrazino groups. In one embodiment, the precursor has a formula of (R′)₂Si(NR″-L-NR″₂)₂, (R′)₂Si(NR″—NR″₂)₂, or (R′)₂Si(NH—NHR″)₂, wherein L, R′, and R″ can be any described herein.

The silicon-containing reactant can include at least two silicon atoms. In one embodiment, the precursor has a formula of (NR″₂—NR″)(R′)₂Si—Si(R′)₂(NR″—NR″₂), wherein each R′ and R″ can be any described herein.

Non-limiting silicon-containing reactants can include bis(tert-butylhydrazino)diethylsilane (SiEt₂[NH—NHtBu]₂); tris(dimethylhydrazino)silane (SiH[NH—NMe₂]₃); and the like.

### Siloxanes and Derivatives Thereof

A silicon-containing reactant can include one or more aliphatic-oxy, aromatic-oxy groups, and/or oxy groups, thereby providing a siloxane or a derivative thereof having one or more Si—O, O—Si—O, or Si—O—Si bonds. In one embodiment, the precursor has a formula of (R′)₄₋ₓSi(OR″)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, silyl, or silyloxy, in which any of these may be optionally substituted.

In another embodiment, the silicon-containing reactant has a formula of (R″O)ₓ(R′)₃₋ₓSi-L-Si(R′)₃₋ₓ(OR″)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, silyl, or silyloxy, in which any of these may be optionally substituted.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic. In other embodiments, L is —O-L′-O—, in which L′ is optionally substituted aliphatic, optionally substituted heteroaliphatic, optionally substituted aromatic, optionally substituted heteroaromatic, optionally substituted silyl (e.g., —SiR₂—), optionally substituted alkylene (e.g., —(CH₂)ₙ—, in which n is 1 to 6), optionally substituted arylene, and the like. In yet other embodiments, L is oxy.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R′)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The silicon-containing reactant can include one or more hydrogen atoms attached to the silicon atom. In one embodiment, the precursor has a formula of H₃Si(OR″). H₂Si(OR″)₂, or HSi(OR″)₂, wherein each R″ can independently be any described herein.

The silicon-containing reactant can include any combination of R′ and OR″ groups within the precursor. In one embodiment, the precursor has a formula of (R′)₃Si(OR″), (R′)₂Si(OR″)₂, or (R′)Si(OR″)₃, wherein each of R′ and R″ can independently be any described herein. The precursor can include alkyl groups, such as in the precursor having a formula of (R^{Ak})₃Si(OR^{Ak}), (R^{Ak})₂Si(OR^{Ak})₂, or (R^{Ak})Si(OR^{Ak})₃, in which R^{Ak} is optionally substituted alkyl.

In some instances, the silicon-containing reactant can have two or more silicon atoms, in which the precursor can include a Si—Si bond. In a particular embodiment, the precursor has a formula of (R″O)ₓ(R′)₃₋ₓSi—Si(R′)₃₋ₓ(OR″)ₓ, wherein R′ and R″ can be any described herein. In one embodiment, the precursor has a formula of (R″O)(R′)₂Si—Si(R′)₂(OR″), wherein R′ and R″ can be any described herein.

The silicon-containing reactant can include a combination of R′ groups with a linker having a heteroatom. In one instance, the precursor has a formula of (R′)₃Si—O—Si(R′)₃, wherein R′ can be any described herein. In another instance, the precursor has a formula of (R′)₃Si—O-L′-O—Si(R′)₃, wherein L′ and R′ can be any described herein. In yet another instance, the precursor has a formula of (R′)₃Si—(OSiR′₂)_{z}—R′, wherein R′ can be any described herein; and in which z is 1, 2, 3, 4, or more. In another instance, the precursor has a formula of (R′)₄₋ₓSi—[(OSiR′₂)_{z}—R′]x, wherein R′ can be any described herein; x is 1, 2, 3, or 4; and z is 1, 2, 3, 4, or more.

The silicon-containing reactant can include any useful combination of R′ and OR″ groups in combination with two silicon atoms. In one instance, the precursor has a formula of (R″O)ₓ(R′)₃₋ₓSi—O—Si(R′)₃₋ₓ(OR″)ₓ, wherein R′ and R″ can be any described herein. In another instance, the precursor has a formula of (R″O)ₓ(R′)₃₋ₓSi—O-L′-O—Si(R′)₃₋ₓ(OR″)ₓ, wherein L′, R′, and R″ can be any described herein.

Non-limiting silicon-containing reactants can include methoxydimethylsilane (SiHMe₂[OMe]); ethoxydimethylsilane (SiHMe₂[OEt]); iso-propoxydimethylsilane (SiHMe₂[OiPr]); t-butoxydimethylsilane (SiHMe₂[OtBu]); t-pentoxydimethylsilane (SiHMe₂[OtPe]); phenoxydimethylsilane (SiHMe₂[OPh]); acetoxydimethylsilane (SiHMe₂[OAc]); methoxvtrimethylsilane (SiMez[OMe]); ethoxytrimethylsilane (SiMe₃[OEt]); iso-propoxytrimethylsilane (SiMe₃[OiPr]); t-butoxytrimethylsilane (SiMe₃[OtBu]); t-pentoxytrimethylsilane (SiMe₃[OtPe]); phenoxytrimethylsilane (SiMe₃[OPh]); acetoxytrimethylsilane (SiMe₃[OAc]); methoxytriethylsilane (SiEt₃[OMe]); ethoxytriethylsilane (SiEt₃[OEt]); iso-propoxytriethylsilane (SiEt₃[OiPr]); t-butoxytriethylsilane (SiEt₃[OtBu]); t-pentoxytriethylsilane (SiEt₃[OtPe]); phenoxytriethylsilane (SiEt₃[OPh]); acetoxytriethylsilane (SiEt₃[OAc]); dimethoxysilane (SiH₂[OMe]₂); diethoxysilane (SiH₂[OEt]₂); di-iso-propoxysilane (SiH₂[OPr]₂); di-tert-butoxysilane (SiH₂[OtBu]₂ or DTBOS); di-tert-pentoxysilane (SiH₂[OtPe]₂ or DTPOS); diacetoxysilane (SiH₂[OAc]₂); dimethoxydimethylsilane (SiMe₂[OMe]₂); diethoxydimethylsilane (SiMe₂[OEt]₂); di-iso-propoxydimethylsilane (SiMe₂[OPr]₂); di-tert-butoxydimethylsilane (SiMe₂[OtBu]₂); diacetoxydimethylsilane (SiMe₂[OAc]₂); dimethoxy diethylsilane (SiEt₂[OMe]₂); diethoxydiethylsilane (SiEt₂[OEt]₂); di-iso-propoxydiethylsilane (SiEt₂[OiPr]₂); di-tert-butoxydiethylsilane (SiEt₂[OtBu]₂); diacetoxydiethylsilane (SiEt₂[OAc]₂); dimethoxydiphenylsilane (SiPh₂[OMe]₂); dimethoxydi-iso-propylsilane (Si[iPr]₂[OMe]₂); diethoxydi-iso-propylsilane (Si[iPr]₂[OEt]₂); di-iso-propoxydi-iso-propylsilane (Si[iPr]₂[OiPr]₂); di-tert-butoxydi-iso-propylsilane (Si[iPr]₂[OtBu]₂); diacetoxydi-iso-propylsilane (Si[iPr]₂[OAc]₂); dimethoxymethylvinylsilane (SiMeVi[OMe]₂); diethoxymethylvinylsilane (SiMeVi[OEt]₂); di-iso-propoxymethylvinylsilane (SiMeVi[OiPr]₂); di-tert-butoxymethylvinylsilane (SiMeVi[OtBu]₂); diacetoxymethylvinylsilane (SiMeVi[OAc]₂); triethoxysilane (SiH[OEt]₃ or TES); trimethoxyethylsilane (SiEt[OMe]₃); triethoxymethylsilane (SiMe[OEt]₃); triethoxyphenylsilane (SiPh[OEt]₃); tetramethoxysilane (Si[OMe]₄); tetraethoxysilane (Si[OEt]₄ or TEOS); tetra-n-propoxysilane (Si[OnPr]₄); tetra-iso-propoxysilane (Si[OiPr]₄); tetra-n-butoxysilane (Si[OnBu]₄); tetra-t-butoxysilane (Si[OtBu]₄); tetramethyldisiloxane (O[SiHMe₂]₂ or TMDO); hexamethyldisiloxane (O[SiMe₃]₂); hexaethyldisiloxane (O[SiEt₃]₂); hexapropyldisiloxane (O[SiPr₃]₂); hexaphenyldisiloxane (O[SiPh₃]₂); hexamethyltrisiloxane (Me₂SiH—O—SiMe₂-O—SiHMe₂); and the like.

### Mixed Silanes Including Oxygen and Nitrogen

A silicon-containing reactant can include one or more optionally substituted amino groups with either aliphatic-oxy or aromatic-oxy groups, thereby providing a non-limiting mixed silane. In one embodiment, the precursor has a formula of (R′)_{z}Si(OR″)ₓ(NR″₂)_{y}, wherein:
each of x and y is, independently, 1, 2, 3, or 4;
z is 0, 1, or 2;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyan, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″ is, independently, H, aliphatic, heteroaliphatic, aromatic, heteroaromatic, silyl, or silyloxy, in which any of these may be optionally substituted.

In another embodiment, the precursor has a formula of (R″₂N)_{y}(R″O)ₓ(R′)_{z}Si-L-Si(R′)_{z}(OR″)(NR″₂)_{y}, wherein:
each of x and y is more than 0 (e.g., 1 or 2);
z is 0 or 1;
x+y+z=3;
L is a linker, such as a covalent bond, optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl; and
each R″ is, independently, H, aliphatic, heteroaliphatic, aromatic, heteroaromatic, silyl, or silyloxy, in which any of these may be optionally substituted.

Non-limiting examples of R′, R″, and R′″ are described herein, e.g., such as for amino silane, siloxane, or derivatives thereof.

The silicon-containing reactant can include any combination of R′, NR″₂, and OR′″ groups. In one embodiment, the precursor has a formula of (R′)Si(OR″)₂(NR″₂) or (R′)₂Si(OR′″)₂(NR″₂), wherein each of R′, R″, and R′″ can independently be any described herein. In other embodiments, the precursor has a formula of (R′)₂Si(OR′″)(N[SiR₃]₂), wherein each of R′ and R′″ can independently be any described herein; and R is, independently, H, optionally substituted aliphatic, optionally substituted heteroaliphatic, optionally substituted aromatic, or optionally substituted heteroaromatic.

The silicon-containing reactant can include only amino and oxy-containing groups attached to the silicon atom. In one embodiment, the precursor has a formula of Si(OR′″)₃(NR″₂), Si(OR′″)₂(NR″₂)₂, or Si(OR′″)(NR″₂)₃, wherein each of R″ and R′″ can independently be any described herein.

Non-limiting silicon-containing reactants can include, e.g., diethoxy(iso-propylamino)silane (SiH[NHiPr][OEt]₂); diethoxy(tert-butylamino)silane (SiH[NHtBu][OEt]₂); diethoxy(tert-pentylamino)silane (SiH[NHtPe][OEt]₂); di-tert-butoxy(methylamino)silane (SiH[NHMe][OtBu]₂); di-tert-butoxy(ethylamino)silane (SiH[NHEt][OtBu]₂); di-tert-butoxy(iso-propylamino)silane (SiH[NHiPr][OtBu]₂); di-tert-butoxy(n-butylamino)silane (SiH[NHnBu][OtBu]₂); di-tert-butoxy(sec-butylamino)silane (SiH[NHsBu][OtBu]₂); di-tert-butoxy(iso-butylamino)silane (SiH[NHiBu][OtBu]₂); di-tert-butoxy(tert-butylamino) silane (SiH[NHtBu][OtBu]₂); di-tert-pentoxy(methylamino) silane (SiH[NHMe][OtPe]₂); di-tert-pentoxy(ethylamino)silane (SiH[NHEt][OtPe]₂); di-tert-pentoxy(iso-propylamino)silane (SiH[NHiPr][OtPe]₂); di-tert-pentoxy(n-butylamino)silane (SiH[NHnBu][OtPe]₂); di-tert-pentoxy(sec-butylamino)silane (SiH[NHsBu][OtPe]₂); di-tert-pentoxy(iso-butylamino) silane (SiH[NHiBu][OtPe]₂); di-tert-pentoxy(tert-butylamino)silane (SiH[NHtBu][OtPe]₂); dimethoxy(phenylmethylamino)silane (SiH[NPhMe][OMe]₂); diethoxy(phenylmethylamino)silane (SiH[NPhMe][OEt]₂); dimethoxy(phenylmethylamino)methylsilane (SiMe[NPhMe][OMe]₂); diethoxy (phenylmethylamino)methylsilane (SiEt[NPhMe][OEt]₂); and the like.

### Silyl Amines

A silicon-containing reactant can include one or more optionally substituted silyl groups attached to a nitrogen atom, thereby providing a non-limiting silyl amine. In one embodiment, the precursor has a formula of (R″)_{3-y}N(SiR′₃)_{y}, wherein:
y is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of (R′₃Si)_{y}(R″)_{2-y}N-L-N(R″)_{2-y}(SiR′₃)_{y}, wherein:
each y is, independently, 0, 1, or 2;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl, optionally in which N-L-N, taken together, forms a multivalent heterocyclyl group.

In one instance, at least one y is not 0. In another embodiment, y can be 0 (e.g., if L includes a carbon atom or a heteroatom). In yet another embodiment, y is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic, a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)₈(OR)_{b}(NR₂)_{c}, —Si(R′)ₐ(OR)_{b}(NR₂)_{c}, —O—SiR′₃, —O—SiR₃, —O—Si(R′)ₐ(OR)_{b}, —O—Si(R′)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted, each R is, independently, H, optionally substituted aliphatic, optionally substituted heteroaliphatic, optionally substituted aromatic, or optionally substituted heteroaromatic, each of a, b, and c≥0, and a+b+c=3 or a+b=3 (if c is not present). In particular embodiments, R is H, optionally substituted alkyl, optionally substituted alkenyl, or optionally substituted alkynyl.

The silicon-containing reactant can include at least one R″ group attached to the nitrogen atom. In one embodiment, the precursor has a formula of (R″)N(SiR′₃)₂ or (R″)₂N(SiR′₃), wherein R′ and R″ can be any described herein. In another embodiment, the precursor has a formula of (R″)₂N(SiH₃) or (R″)N(SiH₃)₂, wherein R″ can be any described herein. In particular embodiments. R′ is optionally substituted alkyl, amino, or alkoxy, and R″ is optionally substituted alkyl or amino, optionally wherein two R″ are taken together, with the nitrogen atom to which each are attached, to form a heterocyclyl.

The silicon-containing reactant can include at least one hydrogen atom attached to the nitrogen atom. In one embodiment, the precursor has a formula of (H)N(SiR′₃)₂, wherein R′ can be any described herein. In another embodiment, the precursor has a formula of (H)N(SiR^{Ak}₃)₂, wherein R^{Ak} can be optionally substituted aliphatic, optionally substituted alkyl, optionally substituted alkenyl, or optionally substituted alkynyl.

The silicon-containing reactant can include three silicon atoms attached to the nitrogen atom. In one embodiment, the precursor has a formula of N(SiR′₃)₃, wherein R′ can be any described herein. In another embodiment, the precursor has a formula of N(SiH₃)(SiR′₃)₂, wherein R′ can be any described herein. In yet another embodiment, the precursor has a formula of N(SiH₃)(SiR^{Ak}₃)₂, wherein R′ can be optionally substituted aliphatic, optionally substituted alkyl, optionally substituted alkenyl, or optionally substituted alkynyl.

The silicon-containing reactant can have two or more nitrogen atoms, in which the precursor includes a N—N bond. In one instance, the precursor has a formula of (R′₃Si)₂N—N(SiR′₃)₂, wherein R′ can be any described herein.

A linker can be present between nitrogen atoms. In one instance, the precursor has a formula of (R′₃Si)(R″)N-L-N(R″)(SiR′₃) or (R′₃Si)₂N-L-N(SiR′₃)₂, wherein R′ and R″ can be any described herein. In some embodiments, L is a covalent bond, optionally substituted alkylene, optionally substituted heteroalkylene, —O—, —SiR₂—, or —Si—. In particular embodiments, at least one of R″ is not H. In another instance, the precursor has a formula of (H₃Si)(R″)N-L-N(R″)(SiH₃), wherein R″ can be any described herein.

The linker can include a silicon atom. In one instance, the precursor has a formula of (R′₃Si)₂N—SiR′₂—N(SiR′₃)₂, wherein R′ can be any described herein. In another instance, the precursor has a formula of (R′₃Si)(R″)N—SiR′₂—N(R″)(SiR′₃) or (R′₃Si)₂N—SiR′₂—N(R″)₂, wherein R′ and R″ can be any described herein.

The linker can include a SiH₂ group. In one instance, the precursor has a formula of (R′₃Si)₂N—SiH₂—N(SiR′₃)₂, wherein R′ can be any described herein. In another instance, the precursor has a formula of (R′₃Si)HN—SiH₂—NH(SiR′₃) or (R′₃Si)₂N—SiH₂—N(R″)₂, wherein R′ and R″ can be any described herein.

A plurality of nitrogen- and silicon-containing moieties may be present within the precursor. In one embodiment, the precursor has a formula of (R′₃Si)(R″)N—SiR′₂—N(R″)—SiR′₂N(R″)(SiR′₃), wherein R′ and R″ can be any described herein.

Non-limiting precursors can include, e.g., 1,1,3,3-tetramethyldisilazane (NH[SiHMe₂]₂ or TMDS); 1,1,2,3,3-pentamethyldisilazane (NMe[SiHMe₂]₂); 1,1,1,3,3,3-hexamethyldisilazane (NH[SiMe₃]₂ or HMDS); heptamethyldisilazane (NMe[SiMe₃]₂), 1,1,1,3,3,3-hexamethyl-2-ethyldisilazane (NEt[SiMe₂]₂), 1,1,1,3,3,3-hexamethyl-2-isopropyldisilazane (NiPr[SiMe₃]₂); 1,1,1,3,3,3-hexaethyl-2-isopropyldisilazane (NiPr[SiEt₃]₂); 1,1,3,3-tetramethyl-2-isopropyldisilazane (NiPr[SiHMe₂]₂); 1,1,3,3-tetraethyl-2-isopropyldisilazane (NiPr[SiHEt₂]), 1,3-diethyltetramethyldisilazane (NH[SiMe₂Et]₂); 1,1,3,3-tetraethyldisilazane (NH[SiHEt₂]₂); 1,1,3,3-tetraethyl-2-methyldisilazane (NMe[SiHEt₂]₂); 1,1,1,3,3,3-hexaethyldisilazane (NH[SiEt₃]₂); 1,1,1,3,3,3-hexaethyl-2-methyldisilazane (NMe[SiEt₃]₂); 1,1,1,2,3,3,3-heptaethyldisilazane (NEt[SiEt₃]₂); 1,2,3-trimethyltrisilazane (N[SiH₂Me]₂); nonamethyltrisilazane (N[SiMe₃]₂); di-iso-propylsilylamine (NiPr₂[SiH₃]); diethylsilylamine (NEt₂[SiH₃]); diisopropylsilylamine (NiPr₂[SiH₃]); di-sec-butylsilylamine (NsBu₂[SiH₃]); di-tert-butylsilylamine (NtBu₂[SiH₃]); disilylmethylamine (NMe[SiH₃]₂), disilylethylamine (NEt[SiH₃]₂); disilylisopropylamine (NiPr[SiH₃]₂); disilyl-tert-butylamine (NtBu[SiH₃]₂); bis(trimethylsilyl) amine (NH[SiMe₃]₂); bis(triethylsilyl)amine (NH[SiEt₃]₂); and the like.

### Silazanes and Derivatives Thereof

A silicon-containing reactant can include one or more amino, silyl, and/or imino groups, thereby providing a silazane or a derivative thereof having one or more Si—N, N—Si—N, Si—N—Si, N—Si—Si, or N—Si—N—Si bonds. In one embodiment, the precursor has a formula of

(R″)_{3-y}N(SiR′2-L-SiR′₃)_{y}, wherein:
y is 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of (R″)_{3-y}N(SiR′2-L-SiR′₂—NR″₂)_{y}, wherein y is 1, 2, or 3; and each of L, R′, and R″ can be any described herein.

In yet another embodiment, the silicon-containing reactant has a formula of (R″)_{3-y}N(SiR′2-L-NR″₂)_{y}, wherein y is 1, 2, or 3; and each of L, R′, and R″ can be any described herein.

In one embodiment, the silicon-containing reactant has a formula of

(R′)₄₋ₓSi(NR″-L-SiR′₃)ₓ, wherein:
x is 1, 2, 3, or 4;
L is a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, all phatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of (R″2N)—(SiR′2-L)_{z}-SiR′₃, wherein z is 1, 2, or 3; and each of L, R′, and R″ can be any described herein.

In some embodiments, L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃ or —SiR₂-L-SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl. L can be any useful linker (e.g., a covalent bond, optionally substituted alkylene, optionally substituted heteroalkylene, oxy, imino, silyl, or the like).

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments. R″ is —SiR′₃, —SiR₃, —Si(R)ₐ(OR)_{b}, —Si(R)ₐ(OR)_{b}, —Si(R)ₐ(NR₂)_{b}, —Si(R)ₐ(NR₂)_{b}, —Si(R)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments. R is H, optionally substituted alkyl, optionally substituted alkenyl, or optionally substituted alkynyl.

The silicon-containing reactant can include one or more disilanyl groups and amino groups. In one embodiment, the precursor has a formula of R″₂N—SiR′₂—SiR′₃, wherein L, R′, and R″ can be any described herein. In other embodiments, the precursor has a formula of R″₂N—SiH₂—SiH₃, wherein R″ is any described herein. In another embodiment, the precursor has a formula of (R″)_{3-y}N—(SiR′₂—SiR′₃)_{y}, wherein y, R′, and R″ can be any described herein. In yet another embodiment, the precursor has a formula of (R″)_{3-y}N—(SiH₂—SiH₃)_{y}, wherein y and R″ can be any described herein.

The silicon-containing reactant can include a bivalent disilanyl group. In one embodiment, the precursor has a formula of R″₂N—SiR′₂—SiR′₂-L-NR″₂, wherein L, R′, and R″ can be any described herein. In another embodiment, the precursor has a formula of R″₂N—SiR′₂—SiR′₂—NR″₂, wherein R′ and R″ can be any described herein.

A linker L can be present between two silyl group. In one embodiment, the precursor has a formula of R″₂N—SiR′2-L-SiR′₃ or R″N—(SiR′2-L-SiR′₃)₂, wherein L, R′, and R″ can be any described herein. In another embodiment, the precursor has a formula of R″₂N—SiR′₂-L-SiR′₂—NR″₂, wherein L, R′, and R″ can be any described herein. In yet another embodiment, the precursor has a formula of (R″)_{3-y}N—(SiR′₂-L-SiH₃)_{y}, wherein y, L, R′, and R″ can be any described herein.

The silicon-containing reactant can include —SiH₃ as the silyl group. In one embodiment, the precursor has a formula of R″₂N—SiH₂—SiH₃, wherein R″ can be any described herein. In another embodiment, the precursor has a formula of (R″)N—(SiH₂-L-SiH₃)₂ or (R″)₂N—(SiH₂-L-SiH₃), wherein L and R″ can be any described herein.

The silicon-containing reactant can include a silyl-substituted amino group, such as, e.g., —NR″—SiR′₃, in which R′ and R″ can be any described herein. In one embodiment, the precursor has a formula of
(R′)₄₋ₓSi(NR″—SiR′₃)ₓ or (R′)₄₋ₓSi(NH—SiR′₃)ₓ, wherein x is 1, 2, 3, or 4; and in which R′ and R″ can be any described herein. In another embodiment, the precursor has a formula of H₂Si(NR″—SiR′₃)₂, wherein R′ and R″ can be any described herein.

The silicon-containing reactant can include a bis-trisilylamino group, such as, e.g., —N(SiR′₃)₂ in which R′ can be any described herein. In one embodiment, the precursor has a formula of R″₂N—SiR′₂—N(SiR′₃)₂, in which R′ and R″ can be any described herein. In another embodiment, the precursor has a formula of R″₂N—SiH₂—N(SiH₃)₂, in which R′ can be any described herein. In yet another embodiment, the precursor has a formula of (R′₃Si)₂N—[SiR′₂—N(SiR′₃)]_{z}(SiR′₃), wherein z is 0, 1, 2, or 3; and in which R′ and R″ can be any described herein.

The silicon-containing reactant can include a linker L disposed between a silicon atom and a nitrogen atom. In one embodiment, the precursor has a formula of R″₂N—SiR′₂-L-NR″₂, wherein L, R′, and R″ can be any described herein.

The silicon-containing reactant can include a linker L disposed between two nitrogen atoms. In one embodiment, the precursor has a formula of wherein L, R′, and R″ can be any described herein.

The linker can include a silylimino group, such as, e.g., —N(SiR′₃)—, in which R′ can be any described herein. In one embodiment, the precursor has a formula of R″₂N—[SiR′₂—N(SiR′₃)]_{z}—SiR′₃ or R″₂N—[N(SiR′₃)]_{z}—SiR′₃, in which z is 1, 2, 3, or more; and wherein R′ and R″ can be any described herein.

The linker can include both a silyl group and an imino group. In one embodiment, the precursor has a formula of R″₂N—[SiR′₂—NR″]_{z}—SiR′₃, in which z is 1, 2, 3, or more; and wherein R′ and R″ can be any described herein.

Non-limiting silicon-containing reactants include, e.g., di-iso-propylaminodisilane ([iPr₂N]—SiH₂—SiH₃); di-sec-butylaminodisilane ([sBu₂N]—SiH₂—SiH₃); methylcyclohexylaminodisilane ([MeCyN]—SiH₂—SiH₃); methylphenylaminodisilane ([MePhN]—SiH₂—SiH₃); piperidinodisilane; 3,5-dimethylpiperidinodisilane; di-iso-propylaminotrisilylamine ([iPr₂N]—SiH₂—N[SiH₃]₂); diethylaminotrisilylamine ([Et₂N]—SiH₂—N[SiH₃]₂); iso-propylaminotrisilylamine ([iPrHN]—SiH₂—N[SiH₃]₂); and the like.

Mixed Amines Including Silicon and Oxygen A silicon-containing reactant can include one or more amino groups substituted with a silyl group, thereby providing a non-limiting mixed amine. In one embodiment, the precursor has a formula of (R″)_{3-y}N[Si(OR)ₓR′₃₋ₓ]y, wherein:
each of x and y is, independently, 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted;
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl, and
each R′″ is, independently, H, aliphatic, heteroaliphatic, aromatic, heteroaromatic, silyl, or silyloxy, in which any of these may be optionally substituted.

Non-limiting examples of R′, R″, and R′″ are described herein, e.g., such as for amino silane, siloxane, silyl amine, or derivatives thereof.

The silicon-containing reactant can include any combination of R″ groups and silicon-containing groups. In one embodiment, the precursor has a formula of (R″)_{3-y}N[Si(OR^{Ak})ₓR^{Ak}₃₋ₓ]_{y} or (R^{Ak})_{3-y}N[Si(OR^{Ak})ₓR^{Ak}₃₋ₓ]_{y}, in which R″, x, and y is any described herein; and wherein R′ is H, optionally substituted aliphatic, or optionally substituted heteroaliphatic. In particular embodiments, R^{Ak} is H, optionally substituted alkyl, optionally substituted alkylene, or optionally substituted alkynyl. In other embodiments, the precursor has a formula of (R″)_{3-y}N[Si(OR)ₓH₃₋ₓ]_{y} or (R″)_{3-y}N[Si(OR^{Ak})H(R^{Ak})]_{y}, in which R″, R^{Ak}, x, and y is any described herein.

The silicon-containing reactant can include two silicon-containing groups. In one embodiment, the precursor has a formula of (R″)N[Si(OR^{Ak})ₓR^{Ak}₃₋ₓ]₂ or (R^{Ak})N[Si(OR^{Ak})ₓR^{Ak}₃₋ₓ]₂, in which R″, R^{Ak}, x, and y is any described herein. In particular embodiments, x is 1 or 2.

The silicon-containing reactant can include a hydrogen atom attached to the nitrogen atom. In one embodiment, the precursor has a formula of (H)_{3-y}N[Si(OR^{Ak})ₓR^{Ak}₃₋ₓ]_{y} or (H)_{3-y}N[Si(OR^{Ak})ₓH₃₋ₓ]_{y} or (H)_{3-y}N[Si(OR^{Ak})H(R^{Ak})]_{y}, in which R^{Ak}, x, and y is any described herein. In particular embodiments, x is 1 or 2.

Non-limiting silicon-containing reactant include, e.g., bis(dimethoxysilyl)amine (NH[Si(OMe)₂H]₂); bis(diethoxysilyl)amine (NH[Si(OEt)₂H]₂); N-iso-propylbis(diethoxysilyl)amine (NiPr[Si(OEt)₂H]₂); bis(methoxymethylsilyl)amine (NH[Si(OMe)MeH]₂); tris(dimethoxysilyl) amine (N[Si(OMe)₂H]₃); tris(methoxymethylsilyl)amine (N[Si(OMe)MeH]₃); tris(diethoxysilyl) amine (N[Si(OEt)₂H]₃); tris(trimethoxysilyl)amine (N[Si(OMe)₃]₃); and the like.

### Cyclic Silazanes

A silicon-containing reactant can include a cyclic group having one or more nitrogen atoms. In one embodiment, the precursor has a formula of [NR″—(SiR′)ₙ]_{z}, wherein:
z is 1, 2, 3, 4, 5, or more;
n is 1, 2, or 3;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In one embodiment, the silicon-containing reactant has a formula of [NR″—(SiR′₂)ₙ-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, amino, silyl, or silyloxy, in which any of these may be optionally substituted; or optionally in which two R″ can be taken together, with the nitrogen atom to which each is attached, to form an optionally substituted heterocyclyl.

In another embodiment, the silicon-containing reactant has a formula of [NR″-L-NR″—(SiR′₂)ₙ]_{z}, wherein: z is 1, 2, 3, 4, 5, or more; each n is, independently, 1, 2, or 3; and in which R′ and R″ can be any described herein.

In yet another embodiment, the precursor has a formula of [L-(SiR′₂)ₙ]_{z}, wherein:
z is 1, 2, 3, 4, 5, or more; each n is, independently, 1, 2, or 3; L is imino (e.g., —NR—), optionally substituted aliphatic, optionally substituted heteroaliphatic, or combinations thereof; and in which R′ can be any described herein. In particular embodiments, if L does not include a heteroatom, then R′ includes one or more heteroatoms (e.g., nitrogen atoms).

In one embodiment, the silicon-containing reactant has a formula of

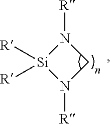

wherein R′ and R″ can be any described herein, and wherein n is 1, 2, 3, or 4.

In another embodiment, the silicon-containing reactant has a formula

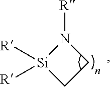

wherein R′ and R″ can be any described herein, and wherein n is 1, 2, 3, or 4.

In yet another embodiment, the silicon-containing reactant has a formula of

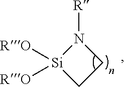

wherein R″ and R″ can be any described herein, and wherein n is 1, 2, 3, or 4. In particular embodiments, each R″ is, independently, H, aliphatic, heteroaliphatic, aromatic, heteroaromatic, silyl, or silyloxy, in which any of these may be optionally substituted.

In one embodiment, silicon-containing reactant has a formula of

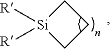

wherein R′ can include a heteroatom (e.g., a nitrogen atom, such as in optionally substituted amino, azido, isocyanato, or optionally substituted hydrazino), and wherein n is 1, 2, 3, or 4.

In some embodiments. L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino (e.g., —NR— or —N(SiR₃)—), or silyl (e.g., —SiR₂—), as well as combinations thereof (e.g., —SiR₂—NR—, —NR—SiR₂—, —SiR₂—NR—SiR₂—, and the like). In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic.

In other embodiments. L is an optionally substituted alkylene, and at least one R′ includes an optionally substituted heteroaliphatic, optionally substituted amino, optionally substituted aliphatic-oxy, or optionally substituted alkoxy.

In some embodiments, each R′ is, independently, H, optionally substituted aliphatic, optionally substituted alkyl, optionally substituted alkenyl, optionally substituted alkynyl, optionally substituted aromatic, or optionally substituted aryl. In other embodiments, each R′ is, independently, optionally substituted heteroaliphatic, optionally substituted amino, or optionally substituted alkoxy.

In other embodiments, each R″ is, independently, H, optionally substituted aliphatic, optionally substituted alkyl, optionally substituted alkenyl, optionally substituted alkynyl, optionally substituted silyl, optionally substituted amino, optionally substituted aromatic, optionally substituted aryl, optionally substituted heteroaromatic, or optionally substituted heteroaryl.

Non-limiting silicon-containing reactants include 1,3,3-trimethylcyclodisilazane ([NH—SiMe₂][NH—SiMeH]); hexamethylcyclotrisilazane ([NH—SiMe₂]₃); octamethylcyclotetrasilazane ([NH—SiMe₂]₄); and the like.

### Cyclic Siloxanes

A silicon-containing reactant can include a cyclic group having one or more oxygen atoms. In one embodiment, the precursor has a formula of [L-(SiR′₂)ₙ]_{z}, wherein:
z is 1, 2, 3, 4, 5, or more;
n is 1, 2, or 3;
L is an oxygen-containing linker (e.g., oxy or heteroalkylene); and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyan, or isocyano, in which any of these may be optionally substituted.

In one embodiment, the silicon-containing reactant has a formula of [O-L′-O—(SiR′₂)ₙ]_{z}, wherein:
z is 1, 2, 3, 4, 5, or more;
n is 1, 2, or 3;
each L′ is, independently, a linker, such as optionally substituted aliphatic, optionally substituted heteroaliphatic, optionally substituted aromatic, optionally substituted heteroaromatic, optionally substituted silyl (e.g., —SiR₂—), optionally substituted alkylene (e.g., —(CH₂)ₙ—, in which n is 1 to 6), and optionally substituted arylene; and
in which R′ is any described herein.

In another embodiment, the silicon-containing reactant has a formula of [O—(SiR′₂)ₙ-L-(SiR′₂)ₙ]_{z}, wherein:
z is 1, 2, 3, 4, 5, or more;
each n is, independently, 1, 2, or 3;
each L is, independently, a linker, such as a covalent bond, optionally substituted aliphatic, optionally substituted heteroaliphatic, optionally substituted aromatic, optionally substituted heteroaromatic, oxy (—O—), imino, or silyl, as well as combinations thereof; and
in which R′ is any described herein.

In yet another embodiment, the silicon-containing reactant has a formula of [L-(SiR′₂)ₙ]_{z}, wherein:
z is 1, 2, 3, 4, 5, or more; each n is, independently, 1, 2, or 3; L is oxy (—O—), optionally substituted aliphatic, optionally substituted heteroaliphatic, or combinations thereof; and in which R′ can be any described herein. In particular embodiments, if L does not include a heteroatom, then R′ includes one or more heteroatoms (e.g., oxygen atoms).

In one embodiment, the silicon-containing reactant has a formula of

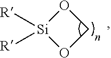

wherein R′ can be any described herein, and wherein n is 1, 2, 3, or 4.

In another embodiment, the silicon-containing reactant has a formula of

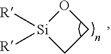

wherein R′ and R″ can be any described herein, and wherein n is 1, 2, 3, or 4.

In yet another embodiment, the silicon-containing reactant has a formula of

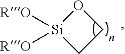

wherein R″ can be any described herein, and wherein n is 1, 2, 3, or 4. In particular embodiments, each R″ is, independently, H, aliphatic, heteroaliphatic, aromatic, heteroaromatic, silyl, or silyloxy, in which any of these may be optionally substituted.

In one embodiment, the silicon-containing reactant has a formula of

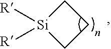

wherein R′ can include a heteroatom (e.g., an oxygen atom, such as in optionally substituted aliphatic-oxy, aliphatic-oxycarbonyl, aliphatic-carbonyl, aliphatic-carbonyloxy, optionally substituted alkoxy, optionally substituted alkoxycarbonyl, optionally substituted alkanoyl, optionally substituted alkanoyloxy, and the like), and wherein n is 1, 2, 3, or 4.

In some embodiments, each R′ is, independently, H, optionally substituted aliphatic, optionally substituted alkyl, optionally substituted alkenyl, optionally substituted alkynyl, optionally substituted aminoalkyl, optionally substituted aromatic, or optionally substituted aryl. In other embodiments, each R′ is, independently, optionally substituted heteroaliphatic, optionally substituted amino, or optionally substituted alkoxy.

Non-limiting silicon-containing reactants include, e.g., tetramethylcyclotetrasiloxane ([OSiHMe]₄ or TMCTS); hexamethylcyclotetrasiloxane ([OSiMe₂OSiHMe]₂ or HMCTS); octamethylcyclotetrasiloxane ([OSiMe₂]₄, C₈H₂₄O₄Si₄, or OMCTS); decamethylcyclopentasiloxane ([OSiMe₂]₅ or C₁₀H₃₀O₅Si₅); 2-dimethylamino-2,4,4,6,6-pentamethylcyclotrisiloxane ([OSiMe₂]₂[OSiMe(NMe₂)]); 2-dimethylamino-2,4,4,6,6,8,8-heptamethylcyclotetrasiloxane ([OSiMe₂]₃[OSiMe(NMe₂)]); and the like.

### Amino Siloxane and Derivatives Thereof

A silicon-containing reactant can include siloxane or a derivative thereof and having one or more amino substitutions, thereby providing a siloxane or a derivative thereof having one or more Si—O, O—Si—O, or Si—O—Si bonds and having one or more —NR₂ substitutions. In one embodiment, the precursor has a formula of (R″)_{3-y}N[SiR′₂—(OSiR′₂)_{z}—R′]_{y}, wherein:
y is 1, 2, or 3;
z is 1, 2, 3, or more;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the silicon-containing reactant has a formula of (R″)_{3-y}N[(SiR′₂—O)_{z}—SiR′₃]_{y}, wherein R′, R″, y, and z can be any described herein.

The silicon-containing reactant can include an optionally substituted amino group with an optionally substituted silyl group. In one embodiment, the precursor has a formula of R″₂N—SiR′₂—(OSiR′₂)_{z}—R′ or R″₂N—SiR′₂—O—SiR′₃, wherein R′, R″, and z can be any described herein, in another embodiment, the precursor has a formula of R″₂N(SiR′₂—O)_{z}—SiR′₃, wherein R′, R″, and z can be any described herein.

The silicon-containing reactant can include two optionally substituted amino group. In one embodiment, the precursor has a formula of R″₂N—SiR′₂—(OSiR′₂)_{z}—NR″₂, wherein R′, R″, and z can be any described herein.

In some embodiments, R′ is H, optionally substituted aliphatic, optionally substituted alkyl, optionally substituted alkenyl, or optionally substituted alkynyl. In other embodiments, R″ is H, optionally substituted aliphatic, optionally substituted alkyl, optionally substituted alkenyl, or optionally substituted alkynyl. In particular embodiments, z is 1, 2, or 3.

Non-limiting silicon-containing reactant can include, e.g., 1-dimethylamino-pentamethyldisiloxane (Me₂N—SiMe₂-OSiMe₃); 1-diethylamino-pentamethyldisiloxane (Et₂N—SiMe₂-OSiMe₃);

1-ethylmethylamino-pentamethyldisiloxane (EtMeN—SiMe₂-OSiMe₃); 1,3-bis(dimethylamino) tetramethyldisiloxane (Me₂N—SiMe₂-OSiMe₂-NMe₂); 1-dimethylamino-heptamethyltrisiloxane (Me₂N—SiMe₂-[OSiMe₂]₂-Me); 1,5-bis(dimethylamino) hexamethyltrisiloxane (Me₂N—SiMe₂-[OSiMe₂]₂—NMe₂); and the like.

### Silanols, Including Alkyl Silanols or Alkoxy Silanols

A silicon-containing reactant can include one or more hydroxyl groups, thereby providing a non-limiting silanol. In one embodiment, the precursor has a formula of (R′)₄₋ₓSi(OH)ₓ, wherein:
x is 1, 2, 3, or 4, and
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted.

In other embodiments, the precursor has a formula of (R′)_{z}Si(OH)ₓ(OR″)_{y}, wherein:
x is 1, 2, 3, or 4;
each of y and z is, independently, 0, 1, 2, or 3;
x+y+z=4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R′ is, independently, H, aliphatic, heteroaliphatic, aromatic, heteroaromatic, silyl, or silyloxy, in which any of these may be optionally substituted.

The silicon-containing reactant can have one hydroxyl group. In one embodiment, the precursor has a formula of (R′)₃Si(OH), in which each R′ can be any described herein. In another embodiment, the precursor has a formula of Si(OH)(OR″)₃, in which each R″ can be any described herein. In particular embodiments, R″ is optionally substituted alkyl (e.g., Me, Et, nPr, iPr, sBu, or tBu), in which the optionally substituted alkyl is linear, branched, substituted, or unsubstituted.

Non-limiting silicon-containing reactant include, e.g., tri(t-butoxy)silanol (SiOH[OtBu]₃); tri(t-pentoxy)silanol (SiOH[OtPe]₃); and the like.

### Carbonyloxy Silanes

A silicon-containing reactant can include one or more optionally substituted aliphatic-carbonyloxy groups, thereby providing a non-limiting carbonyloxy silane. In one embodiment, the precursor has a formula of (R′)₄₋ₓSi(OC(O)—R′″)ₓ, wherein:
x is 1, 2, 3, or 4;
each R′ is, independently, H, aliphatic, aliphatic-carbonyl, aliphatic-oxy, aliphatic-oxycarbonyl, heteroaliphatic, heteroaliphatic-carbonyl, heteroaliphatic-oxy, heteroaliphatic-oxycarbonyl, aromatic, aromatic-carbonyl, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R′″ is, independently, H, aliphatic, heteroaliphatic, aromatic, heteroaromatic, amino, or aminooxy, in which any of these may be optionally substituted.

In another embodiment, the silicon-containing reactant has a formula of (R′″—C(O)O)ₓ(R′)₃₋ₓSi-L-Si(R′)₃₋ₓ(OC(O)—R′″)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-oxy, aliphatic-oxycarbonyl, heteroaliphatic, heteroaliphatic-carbonyl, heteroaliphatic-oxy, heteroaliphatic-oxycarbonyl, aromatic, aromatic-carbonyl, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R′″ is, independently, H, aliphatic, heteroaliphatic, aromatic, heteroaromatic, amino, or aminooxy, in which any of these may be optionally substituted.

In some embodiments, R′ is H, optionally substituted amino (e.g., —NR—), aliphatic-oxy (e.g., alkoxy or —OR), aliphatic-carbonyl (e.g., alkanoyl or —C(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently. H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In some embodiments, R′″ is H, optionally substituted alkyl, optionally substituted alkenyl, optionally substituted alkynyl, optionally substituted alkoxy, optionally substituted aryloxy, optionally substituted amino, or optionally substituted aminooxy.

Non-limiting silicon-containing reactants include those having a formula of (R′)₂Si(OC(O)—R′″)₂, wherein R′ and R′″ can be any described herein.

### Molybdenum-Containing Precursor

Generally, molybdenum-containing precursors can include molybdenum in a wide range of oxidation states ranging from 0 to +6. In some embodiments, molybdenum compounds with molybdenum in low oxidation states +3, +4 and +5 are preferred. Provided methods are particularly useful for depositing molybdenum-containing materials from halogen-containing molybdenum-containing compounds, because silicon-containing reactants can assist in halogen scavenging, but halogen-free molybdenum-containing precursors can be used as well. Suitable molybdenum-containing precursors include molybdenum halides and oxyhalides, such as fluorides, chlorides, bromides, oxyfluorides, oxychlorides, and oxybromides where molybdenum may be in any of the oxidation states from +2 to +6. Examples of suitable halogen-free molybdenum-containing precursors include halogen-free organometallic molybdenum-containing precursors, such as bis(ethylbenzene)molybdenum.

In order to maintain appropriate volatility, in many embodiments discussed herein, the precursors having molecular weights of less than about 450 g/mol, such as less than about 400 g/mol are selected.

In some embodiments the molybdenum containing precursor has a formula MoXₙYₘ, wherein X is a chalcogen (e.g., oxygen or sulfur), Y is a halogen (e.g., fluorine, chlorine, bromine, or iodine), n is 0, 1, or 2 and m is 2, 3, 4, 5, or 6. Examples of halogen-containing molybdenum-containing precursors include without limitation MoCl₅, Mo₂Cl₁₀, MoO₂Cl₂, and MoOCl₄. Another example of a halogen-containing molybdenum-containing precursor is MoF₆.

In some embodiments molybdenum-containing precursor includes carbonyl ligands. Example of a carnyl-containing precursor is Mo(CO)₆.

### Halide-Containing Heteroleptic Molybdenum Compounds

In one aspect, halide-containing heteroleptic molybdenum compounds are used as precursors for deposition of molybdenum-containing films, such as for deposition of molybdenum metal. In one embodiment, the precursor is a compound that includes molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and α-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

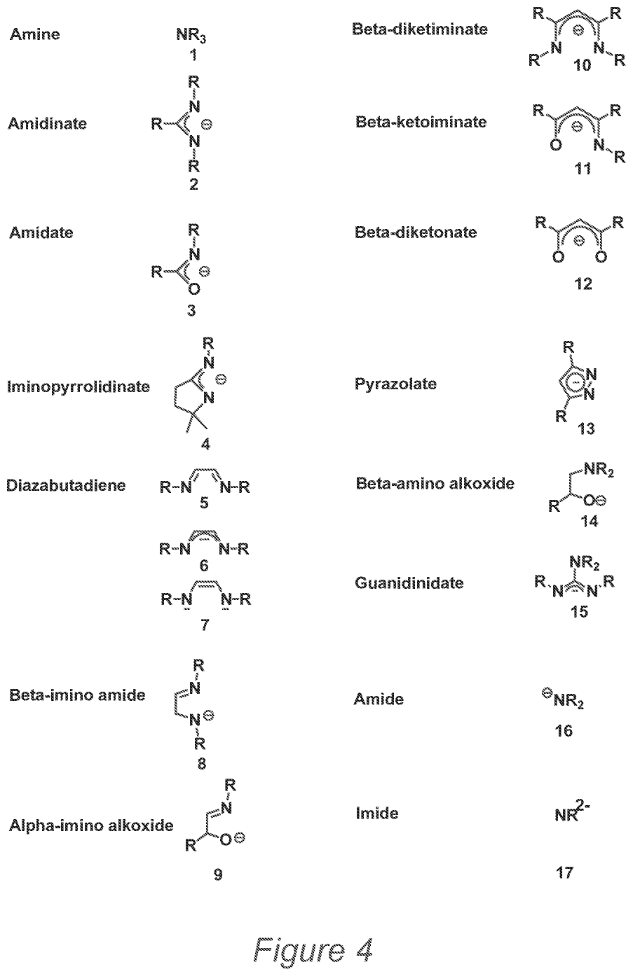

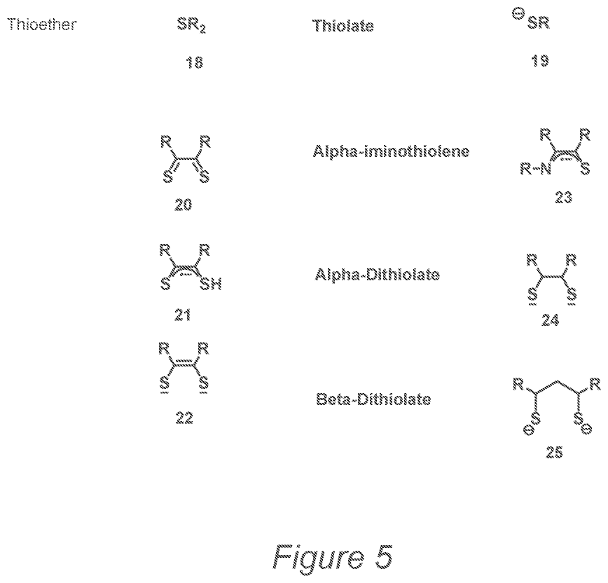

Structures of exemplary suitable N and/or O containing organic ligands 1-17 are shown in FIG. 4, and structures of exemplary suitable S-containing organic ligands 18-26 are shown in FIG. 5, where each R is independently selected from H, alkyl, fluoroalkyl, alkylsilyl, alkylamino, and alkoxy. In some embodiments, each R is independently selected from H, alkyl, and fluoroalkyl. In some embodiments each R is independently selected from H, methyl, ethyl, n-propyl, isopropyl, isobutyl, n-butyl, sec-butyl, t-butyl, pentyl, hexyl, cyclopropyl, cyclobutyl, cyclopentyl, cyclohexyl, cyclopropylmethyl, cyclopropylethyl, cyclopropylpropyl, cyclobutylmethyl, and cyclobutylethyl. In some embodiments each R is an independently selected alkyl. In some embodiments ligands with branched alkyl substituents, such as isopropyl, and isobutyl are preferred, because such ligands provide more volatile molybdenum precursors.

In some embodiments, at least one organic ligand in the precursor is an amine. Suitable amines include unidentate amines (e.g., monoalkylamines, dialkylamines), bidentate amines (e.g., unsubstituted or N-alkyl substituted ethylenediamines), and amines of higher denticities (e.g., substituted or unsubstituted diethylenetriamine). An example of a monodentate amine is amine 1, shown in FIG. 1, where at least one R is an alkyl or fluoroalkyl, and each R is independently selected from the group consisting of H, alkyl, and fluoroalkyl. In some embodiments at least one R is an alkyl, and each R is independently selected from H, and an alkyl. In some embodiments, the at least one organic ligand is an amide, such as a monoanionic amide 16, wherein at least one R is an alkyl or fluoroalkyl, and each R is independently selected from H, alkyl, and a fluoroalkyl. In some embodiments, the at least one organic ligand is an imide, such as a dianionic imide 17, wherein R is an alkyl or fluoroalkyl. While in general imide-containing precursors can be used for deposition of a variety of molybdenum-containing films (including molybdenum metal), in some embodiments they are more preferred for deposition of molybdenum nitride and molybdenum carbonitride, as they form strong molybdenum-nitrogen bonds, and can serve as sources of nitrogen for the resulting film. In some embodiments, at least one organic ligand in the precursor is an amidinate. An example of an amidinate is an amidinate 2 shown in FIG. 4, where each R is independently selected from H, alkyl, and fluoroalkyl. Amidinate 2 is a monoanionic ligand that can form two molybdenum-nitrogen bonds, serving as a bidentate ligand.

In some embodiments, at least one organic ligand in the precursor is an amidate. An example of an amidate is an amidate 3 shown in FIG. 2, where each R is independently selected from H, alkyl, and fluoroalkyl. Amidate 3 is a monoanionic ligand that can form one molybdenum-nitrogen, and one molybdenum-oxygen bond, serving as a bidentate ligand.

In some embodiments, at least one organic ligand in the precursor is a diazadiene. Examples of diazadienes are 1,4-diazabuta-1,3-dienes (DAD) 5, 6, and 7, where each R is independently selected from H, alkyl, and fluoroalkyl. An interesting property of this ligand is that it can exist in neutral form 5, monoanionic radical form 6, and dianionic form 7. Due to redox activity of monoanionic (radical) form 6, it can be relatively easily removed during deposition making complexes of DAD 6 particularly useful for deposition of molybdenum metal and high purity molybdenum metal. DAD ligands 5, 6, and 7 can serve as bidentate ligands, each forming two molybdenum-nitrogen bonds. In some embodiments the molybdenum precursor includes DAD ligand 5, 6, or 7 as an organic ligand, where each R is independently selected from methyl, ethyl, propyl, isopropyl, n-butyl, isobutyl, sec-butyl and t-butyl.

In some embodiments, the at least one organic precursor is an iminopyrrolidinate (such as an iminopyrrolidinate 4, where each R is independently selected from H, alkyl, and fluoroalkyl), a beta-imino amide (such as beta-imino amide 8, where each R is independently selected from H, alkyl, and fluoroalkyl), an alpha-imino alkoxide (such as an alpha-imino alkoxide 9, where each R is independently selected from H, alkyl, and fluoroalkyl), a beta-diketiminate (such as an beta-diketiminate 10, where each R is independently selected from H, alkyl, and fluoroalkvl), a beta-ketoiminate (such as beta-ketoiminate 11, where each R is independently selected from H, alkyl, and fluoroalkyl), a beta-diketonate 12 (such as beta-diketonate 12, where each R is independently selected from H, alkyl, and fluoroalkyl), a pyrazolate (such as pyrazolate 13, where each R is independently selected from H, alkyl, and fluoroalkyl), a beta-aminoalkoxide (such as beta-aminoalkoxide 14, where each R is independently selected from H, alkyl, and fluoroalkyl), or a guadinidate 15 (such as guadinidate 15, where each R is independently selected from H, alkyl, and fluoroalkyl). These are monoanionic ligands that are capable of binding to molybdenum in bidentate manner.

In some embodiments, the at least one organic precursor is a sulfur containing ligand that is capable of forming molybdenum-sulfur bond. In some embodiments the at least one organic ligand in the precursor is a thioether. The term “thioether” is used herein broadly to include to include both unidentate and multidentate (e.g. bidentate of tridentate) thioethers, as well as ligands that contain both thioether and thiolate (or other) moieties. An example of a unidentate thioether is dialkylsulfide R₂S, where each R is an alkyl, such as dimethylsulfide, di ethyl sulfide, diisobutyl sulfide, and the like. An example of a multidentate thioether ligand that also includes thiolate moieties is (SCH₂CH₂SCH₂CH₂S)²⁻ An example of a monodentate thioether is thioether 18, shown in FIG. 5, where each R is independently selected from the group consisting of alkyl, and fluoroalkyl. In some embodiments each R is independently selected from the group consisting of methyl, ethyl, n-propyl, isoropyl, n-butyl, isobutyl, sec-butyl, and t-butyl. In some embodiments, the at least one organic ligand is a thiolate, such as a monoanionic thiolate 19, wherein R is an alkyl or fluoroalkvl. For example, R can be methyl, ethyl, n-propyl, isoropyl, n-butyl, sec-butyl, isobutyl, or t-butyl. In some embodiments the thiolate is a dithiolate, such as dianionic alpha-dithiolate 24, (where each R is independently selected from H, alkyl, and fluoroalkyl) or dianionic beta-dithiolate 25 (where each R is independently selected from H, alkyl, and fluoroalkyl). Dithiolates are capable of forming two molybdenum-sulfur bonds with molybdenum.

In some embodiments, the at least one organic ligand in the precursor is a dithiolene. Examples of dithiolenes are structures 20, 21, and 22, where each R is independently selected from H, alkyl, and fluoroalkyl. This ligand (similarly to DAD) can exist in a neutral form 20, monoanionic radical form 21, and dianionic form 22. Due to redox activity of the monoanionic radical form 21, it can be relatively easily removed during deposition and reduction of molybdenum precursor, making complexes of dithiolene 21 particularly useful for deposition of molybdenum metal and high purity molybdenum metal. Dithiolene ligands 20, 21, and 22 can serve as bidentate ligands, each capable of forming two molybdenum-sulfur bonds. In some embodiments the molybdenum precursor includes dithiolene ligand 20, 21, and/or 22 as an organic ligand, where each R is independently selected from methyl, ethyl, propyl, isopropyl, n-butyl, sec-butyl, isobutyl, and t-butyl.

In some embodiments, the at least one organic ligand in the precursor is an alpha-iminothiolene, such as structure 23, where each R is independently selected from H, alkyl, and fluoroalkyl. In some embodiments each R substituent at the carbon atoms is independently selected from H, alkyl, fluoroalkyl, alkylsilyl, alkylamino, and alkoxy substituents, while R substituent at the nitrogen is independently selected from an alkyl and fluoroalkyl. In some embodiments R substituent at the nitrogen is independently selected from methyl, ethyl, propyl, isopropyl, n-butyl, sec-butyl, isobutyl and t-butyl. This ligand (similarly to DAD, and dithiolene) has a monoanionic radical form, as shown in structure 23, is redox-active, and easily removable during reduction processes.

In some embodiments the precursor is a compound having a formula Mo(X)ₘ(L)ₙ, where m is selected from 1-4, n is selected from 1-3, each X is a halide independently selected from F, Cl, Br, and I and each L is an organic ligand as described above, e.g., a ligand independently selected from amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates, thioethers, thiolates, dithiolenes, dithiolates, and α-imino thiolenes. In some embodiments in the named ligands each R is independently selected from H, alkyl, and fluoroalkyl.

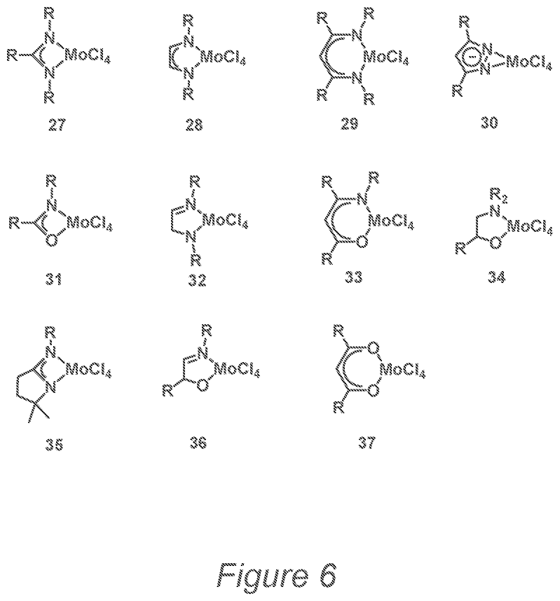

In some embodiments L is a bidentate ligand. Examples of suitable molybdenum-containing precursors of formula Mo(L)Cl₄, that utilize bidentate ligands are shown in FIG. 6. These are Mo(V) compounds and include an amidinate molybdenum complex 27, a DAD complex 28, a beta-diketiminate complex 29, a pyrazolate complex 30, an amidate complex 31, a beta-imino amide complex 32, a beta-ketoiminate complex 33, a beta-amino alkoxide complex 34, an iminopyrrolidinate complex 35, an alpha-imino alkoxide complex 36, and a beta-diketonate complex 37.

The heteroleptic complexes with molybdenum-halide bonds and organic ligands described herein can be synthesized using a reaction of molybdenum halide starting materials with the compounds comprising organic ligands in neutral or anionic form. For example, molybdenum(V) precursors may be prepared using MoCl₅ as a starting material. Mo(III) precursors may be prepared using MoX₃(THF)₃ as a starting material, where X is selected from chloride, bromide, and iodide, and THF is tetrahydrofuran. The starting materials can be treated with the ligand in a neutral or anionic form (e.g. a salt, such as lithium or sodium salt), to form the heteroleptic complexes described herein.

The heteroleptic molybdenum compounds containing molybdenum-halide bonds and organic ligands described herein can advantageously provide high purity molybdenum metal in CVD-type and ALD-type deposition methods provided herein. Further, the use of these compounds can be associated with reduced etching of the substrate materials as compared with conventional homoleptic molybdenum halides. These advantages are described for illustration purposes and do not limit the use of these compounds solely to molybdenum metal deposition or to deposition on etching-sensitive substrates.

In some embodiments, when deposition is conducted on fluorine-sensitive materials (e.g., silicon-containing materials) the precursors are selected to be fluorine free, e.g., include any of the Cl, Br, and I as the halides in the complex. Further, the use of compounds with fluoroalkyl substituents may be avoided in these embodiments.

### Sulfur-Containing Molybdenum Compounds

In one aspect, sulfur-containing molybdenum compounds are used as molybdenum-containing precursors for deposition of molybdenum-containing films, such as for deposition of molybdenum metal and molybdenum silicide. In some embodiments, the molybdenum compounds include molybdenum, and at least one sulfur-containing ligand providing molybdenum-sulfur bonding. Molybdenum precursors which are based on sulfur-containing ligands can be used to deposit molybdenum-containing films which are substantially free of impurities due to the ease of removal of sulfur impurities compared to oxygen, carbon, and nitrogen impurities. In some embodiments, the molybdenum compounds do not include molybdenum-carbon bonds and/or do not include molybdenum-oxygen double bonds. In some embodiments the molybdenum compounds do not include molybdenum-nitrogen double bonds. In some embodiments in the provided molybdenum precursors molybdenum forms bonds only with sulfur atoms.

Examples of suitable sulfur-containing ligands that provide sulfur bonding include thioethers, thiolates, dithiolenes, dithiolates, thiocarbamates, and α-imino thiolenes. The ligands can include one or more substituents independently selected from the group consisting of H, alkyl, fluoroalkyl, alkylsilyl, alkylamino, and alkoxy substituents. The ligands can be neutral or anionic (e.g., monoanionic or dianionic), and molybdenum can be in a variety of oxidation states, such as 0, +1, +2, +3, +4, +5, and +6.

In some embodiments the sulfur-containing ligands are ligands 18-25 shown in FIG. 5, where R substituents are as previously described. Examples of suitable molybdenum precursors include molybdenum thiolates Mo(SR)₄, wherein R is an alkyl, e.g., methyl, ethyl propyl, butyl. In one specific example, the precursor is tetrakis(tert-butylthiolato)molybdenum(IV): Mo(SR)₄, wherein R is t-butyl. Another example of suitable molybdenum precursors are molybdenum thiocarbamates, such as tetrakis(diethyldithiocarbamato)molybdenum(IV):

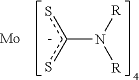

where each R is independently selected from alkyl (e.g., ethyl, methyl, propyl, butyl), and fluoroalkyl (e.g., CF₃). In one specific example the precursor is tetrakis(diethyldithiocarbamato)molybdenum(IV).

In some embodiments dithiolene complexes of molybdenum are provided, where dithiolene may be in any of a neutral form 20, anion-radical form 21, and dianionic form 22, where each R is independently H, alkyl or fluoroalkyl.

Dithiolene complexes are redox-active and can support molybdenum in a variety of oxidation states. Redox reactions of dithiolene ligands 20, 21, and 22 are shown in Equation

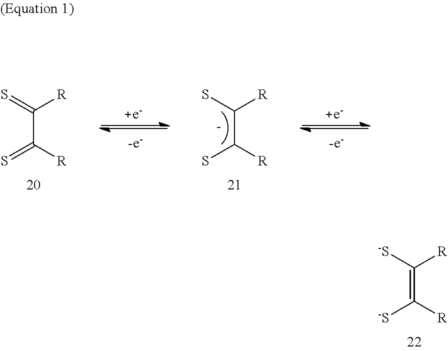

In one implementation, the precursor is Mo(21)₃, where each R in 21 is independently selected from H, alkyl, and fluoroalkyl. For example, R may be methyl, ethyl, CF₃, etc. This is a homoleptic Mo(III) compound containing exclusively molybdenum-sulfur bonds.

In some embodiments, the ligands may provide nitrogen bonding in addition to sulfur bonding. One example of such ligand is alpha-iminothiolene 23, which is a redox-active radical anion ligand that can exhibit behavior similar to that of thiolenes. In some embodiments the precursor is Mo(III) compound Mo(23)₃, where each R in compound 23 is independently selected from H, alkyl, and fluoroalkyl.

In some embodiments, the precursor is MoLₙ compound, where n is from 2 to 6, and L is a sulfur-containing ligand, such as any of the sulfur-containing ligands described herein. In some embodiments each L is the same sulfur-containing ligand. In other embodiments the precursor may include different sulfur containing ligands L. Examples of precursors include Mo(19)₂, Mo(19)₃, Mo(19)₄, Mo(19)₅, Mo(19)₆, Mo(19)₂(18)₂, Mo(19)₃(18), Mo(19)₄(18)₂, Mo(21)₃, Mo(20)(21)₂, Mo(22)₃, Mo(21)(22)₂, Mo(20)(22)₂, Mo(23)₃, Mo(24)₃, Mo(25)₃. The sulfur-containing molybdenum compounds described herein can be synthesized using a reaction of molybdenum halide starting materials with the compounds comprising organic sulfur-containing ligands in neutral or anionic form. For example, molybdenum(V) precursors may be prepared using MoCl₅ as a starting material. Mo(III) or Mo(TV) precursors may be prepared using corresponding halides or MoX₃(L)₃ or MoX₄(L)₂ as a starting material, where X is selected from chloride, bromide, and iodide, and L is a neutral Lewis base such as tetrahydrofuran or diethyl ether. The starting materials can be treated with the desired sulfur-containing ligand in a neutral or anionic form (e.g. a salt, such as lithium or sodium salt), to form the sulfur-containing complexes described herein.

In one example, Mo(IV) thiolato complexes are prepared by reacting molybdenum tetrachloride with lithium thiolates. For example MoCl₄ can be reacted with t-BuSLi in 1,2-dimethoxythane solvent to form Mo(t-BuS)₄ compound.

α-Iminothiolene ligands can be prepared from the corresponding α-iminoketone by thionation using a suitable reagent such as Lawesson's reagent. The radical anionic form of the α-iminothiolene can be prepared subsequently by treatment with an alkali metal, such as lithium. The resulting ligands and ligand salts can be reacted with molybdenum halides to form α-iminothiolene-containing molybdenum compounds.

Molybdenum complexes can also be prepared using compounds, where molybdenum is in a zero oxidation state, such as molybdenum hexacarbonyl. The starting material can be treated with a neutral ligand, such as a thioether (dialkylsulfide), to induce redox neutral ligand exchange. The zero valent starting material can also be treated with a ligand precursor, such as bis(diethylthiocarbamoyl)disulfide or bis(trifluoromethyl)-1,2-dithiete, to induce oxidative addition and form the sulfur-containing complexes described herein.

The reactions may be conducted in a variety of non-protic solvents. For example the reaction may be conducted in an ether solvent, such as tetrahydrofuran, 2-methyltetrahydrofuran, diethyl ether, methyl-tert-butyl ether, 1,2-dimethoxyethane, in a hydrocarbon solvent such as toluene, benzene, heptane, hexane, pentane, or in a halocarbon solvent such as chlorobenzene, dichlorobenzene, fluorobenzene, difluorobenzene, dichloromethane, chloroform, etc. The reactions can be conducted in a wide temperature range depending on the boiling point of the solvent and on solubility of the products. In some embodiments, the starting materials, reaction intermediates, and the desired products are unstable toward moisture and oxygen. Accordingly, the reaction process should be conducted using anhydrous and air-free conditions using a protective inert gas, such as nitrogen or argon.

### 1,4-Diazabutadiene (DAD) Containing Precursors

In another aspect, DAD-containing molybdenum-containing precursors are provided. DAD can bind to molybdenum in its neutral form 5, in its radical-anionic form 6, and in its dianionic form 7. In some embodiments, homoleptic DAD complexes are provided of formula Mo(DAD)m, where m is from 1 to 3, and each DAD is independently selected from neutral DAD 5, radical-anionic DAD 6, and dianionic DAD 7. The oxidation state of molybdenum in these complexes can range from 0 to +6. Non-limiting examples of suitable homoleptic DAD complexes include tris-DAD Mo(III) precursor Mo(6)₃, bis-DAD Mo(IV) precursor Mo(7)₂, bis-DAD Mo(III) precursor Mo(6)(7), and bis-DAD Mo(II) precursor Mo(6)₂.

In some embodiments homoleptic DAD complexes are prepared using a reaction between molybdenum halide and a source of DAD ligand in the required electronic configuration. For example, tris-DAD Mo(III) precursor Mo(6)₃ can be synthesized by reacting MoCl₃ with three equivalents of the radical anion form of the DAD ligand, which can be prepared from the neutral form of the DAD ligand by treatment with an alkali metal, such as lithium, in a solvent, such as THF, as shown in Equation 2

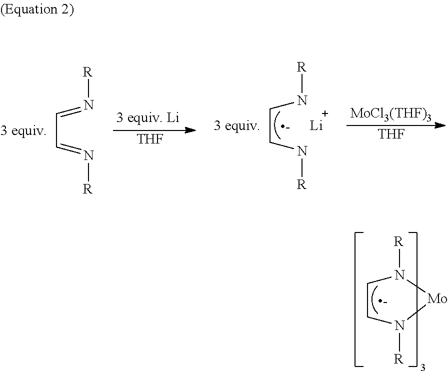

In some embodiments, heteroleptic DAD-containing molybdenum compounds are provided. In some implementations the precursor includes molybdenum, at least one DAD ligand bound to molybdenum, and at least one second ligand, wherein the DAD may be neutral DAD 6, radical anionic DAD 7, or dianionic DAD 8, and the second ligand is independently selected from anionic ligands and neutral ligands. In some embodiments the precursor does not contain CO ligands as the only second ligands. In some embodiments the precursor is MO(DAD)ₘ(L)ₙ(X)ₚ, where L is a neutral Lewis base ligand and each L is independently selected from CO, an amine, a phosphine, a thioether, a nitrile, and an isonitrile, and X is an anionic ligand, and each X is independently selected from a halide, an alkyl, an allyl, and a cyclopentadienyl, and m is 1-3, n is 0-4, and p is 0-4. Nitriles are RCN compounds, where R is an alkyl. Isonitriles are RNC compounds, where R is an alkyl. Other suitable anionic ligands include alkoxides, amides, imides, and any other anionic ligands that include a donor atom chosen from C, N, O, B, S, Si, Al, and P.

Examples of heteroleptic DAD-containing precursors include without limitation Mo(7)₂(RCN)Cl, Mo(7)₂(RNC)Cl, Mo(8)(CO)₃, Mo(6)(13)Cl, Mo(6)(18)Cl₂, Mo(6)₂Cl, Mo(6)₂(14), Mo(6)₂(19), Mo(6)₂(24).

Heteroleptic DAD-containing precursors can be prepared by sequential salt metathesis reactions in one pot or using multiple steps. Molybdenum halide starting materials such as Mo(V), Mo(IV), or Mo(III) halides can be treated with anionic forms of a DAD ligand or other anionic ligands. Neutral Lewis base ligands can be exchanged using thermal treatment or photoexcitation.

Heteroleptic DAD-containing precursors can also be prepared using a zero valent molybdenum starting material, such as molybdenum hexacarbonyl, which can undergo oxidative addition with redox active ligands, such as DAD ligands.

In some embodiments, the precursors containing radical anionic DAD ligand 8 are particularly preferred for deposition of molybdenum metal and high purity molybdenum metal. In the radical anionic form 7, the DAD ligand is electronically coupled to vacant molybdenum d-orbitals and is believed to serve as a source of electrons which reduce the molybdenum ions to the zerovalent metallic state. After ligand-to-metal electron transfer, the volatile, neutral DAD ligand 6 can be purged away from the molybdenum metal growth surface. Since the DAD ligand can be removed intact from the growth surface, incorporation of impurity elements such as C and N are reduced when using DAD precursors as compared to other metalorganic precursors. Therefore, molybdenum precursors containing radical anionic DAD ligands can be used for depositing high purity molybdenum metal at low temperatures.

### Di-Molybdenum Precursors

In another aspect, precursors for deposition of molybdenum-containing films are di-molybdenum compounds containing a molybdenum-molybdenum bond (e.g., a multiple molybdenum-molybdenum bond, such as a double bond, or any multiple bond with a bond order of 2-5). Such precursors are particularly useful for deposition of molybdenum metal and high purity molybdenum metal because it is easier to reduce such compounds to metallic molybdenum than many mononuclear molybdenum compounds.

In some embodiments, a precursor for deposition of molybdenum-containing films is provided, wherein the precursor is Mo₂Lₙ, wherein each L is independently selected from amidate, amidinate, and guanidinate ligands, n is 2-5, and where the precursor includes a multiple molybdenum-molybdenum bond. In some embodiments each L is independently selected from an amidinate ligand 2, amidate ligand 3, and a guanidinate ligand 15, wherein each R in the amidinate, amidate, and guanidinate is independently selected from H, alkyl, fluoroalkyl, alkylsilyl, alkylamino, and alkoxy substituents. In some embodiments each R is independently selected from H, alkyl, and fluoroalkyl. In some embodiments each L is an amidinate and the precursor has a formula Mo₂(L)₃ or Mo₂(L)₄. In some embodiments each L is an amidinate and the precursor has a formula Mo₂(L)₃ or Mo₂(L)₄. In some embodiments each L is a guanidinate and the precursor has a formula Mo₂(L)₃ or Mo₂(L)₄. In these complexes molybdenum has a low oxidation state 2+ (in Mo₂(L)₃) and 3+ in (Mo₂(L)₄) making these complexes particularly suitable for facile reduction to molybdenum metal.

One exemplary structure of an amidate paddlewheel di-Mo (II) precursor having a quadruple molybdenum-molybdenum bond is shown by structure 38:

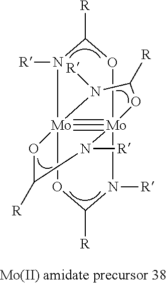

In some embodiments each of R and R′ is independently selected from alkyls, such as methyl, ethyl, isopropyl, and t-butyl. In some embodiments one, two, three or four amidate ligands in 38 may be substituted by amidinate or guanidinidate ligands.

Di-molybdenum precursors described herein can be synthesized using dimolybdenum tetraacetate as a starting material by treatment with a ligand salt such as lithium amidate.

### Cobalt Precursors

Cobalt metal can be deposited using a variety of cobalt precursors, where cobalt may be in +1, +2 or +3 oxidation states. Examples of cobalt precursors include cobalt acetate, cobalt acetylacetonates (e.g., cobalt (III) bis(acetylacetonate)), cobalt amidinates (e.g., bis(N-t-butyl-N′-ethylpropanimidamidato)cobalt(II)) cobaltocene, and carbonyl-containing cobalt precursors (e.g., cobalt tricarbonyl nitrosyl, and cyclopentadienylcobalt dicarbonyl). An example of a halogen-containing cobalt precursor is CoCl₂(TMEDA), where TMEDA is N,N,N′,N′-tetramethylethylenediamine.

### Ruthenium Precursors

Ruthenium metal can be deposited, for example, using vaporizable ruthenium precursors, such as bis(ethylcyclopentadienyl)ruthenium(II), bis(pentamethylcvclopentadienvl)ruthenium, ruthenocene, and cyclopentadienyl-propylcyclopentadienyl ruthenium(II).

### Tungsten Precursors

Tungsten can be deposited using a variety of volatile precursors. In some embodiments halogen-containing tungsten precursors, such as WHalₓ, where Hal is a halogen (e.g., F, Cl, Br, and/or I) and x is from 2 to 6, are used. In some embodiments tungsten chloride is used. Tungsten chloride includes tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride may be used.

### Reducing Agent

A number of reducing agents can be used for deposition of molybdenum-containing films or other metal-containing films provided herein. In some embodiments the reducing agent is selected such that it is capable of reducing the molybdenum-containing precursor to molybdenum metal, or any other metal precursor to a metal in zero oxidation state. In some embodiments, partial reduction of the molybdenum-containing precursor (or other metal precursor) may be carried out by the silicon-containing reactant, and the reducing agent functions to reduce the partially reduced molybdenum-containing precursor to molybdenum metal (or other metal precursor to metal). For example, the silicon-containing reactant may reduce Mo(V) precursors, such as MoCl₅ to Mo(IV) or Mo(III) state, such as MoCl₄ or MoCl₃. The reducing agent then would reduce these partially reduced precursors further to molybdenum metal. Examples of suitable reactants for forming molybdenum metal include hydrogen (H₂), ammonia (NHS), hydrazine (N₂H₄), an amine, diborane (B₂H₆), silane (SiH₄), disilane (Si₂H₆), an alcohol, hydrogen sulfide (H₂S), a thiol, and combinations thereof. In some embodiments the reducing agent is hydrogen. It is noted that when the reducing agent is a silicon-containing compound (e.g., silane), the silicon-containing reactant can still be employed for surface modification. For example, the deposition process may involve exposing the substrate to a silicon-containing reactant for a period of time (e.g., at least 10 seconds or at least 15 seconds) to modify a surface of a substrate containing an exposed metal layer and an exposed dielectric layer, followed by exposure to the silicon-containing reducing agent and a molybdenum-containing precursor. In some embodiments the silicon-containing reactant and the silicon-containing reducing agent are different.

### Apparatus

The deposition methods described herein can be carried out in a variety of apparatuses. A suitable apparatus includes a processing chamber having one or more inlets for introduction of reactants, a substrate holder in the process chamber configured to hold the substrate in place during deposition, and, optionally, a plasma generating mechanism configured for generating a plasma in a process gas. The apparatus may include a controller having program instructions configured to cause performance of any of the method steps described herein. The deposition methods described herein may be carried out in corresponding ALD and CVD apparatuses available from Lam Research Corp. of Fremont, CA, such as Altus®, Vector®, and Striker® tools.

For example, in some embodiments the apparatus includes a controller having program instructions that include instructions for: causing exposure of a semiconductor substrate to a silicon-containing reactant, a molybdenum-containing precursor, and a reducing agent at a temperature of between about 100° C. and about 500° C. in any of the process sequences described herein to deposit molybdenum metal and/or molybdenum silicide. The controller may include program instructions for causing any of the methods described herein.

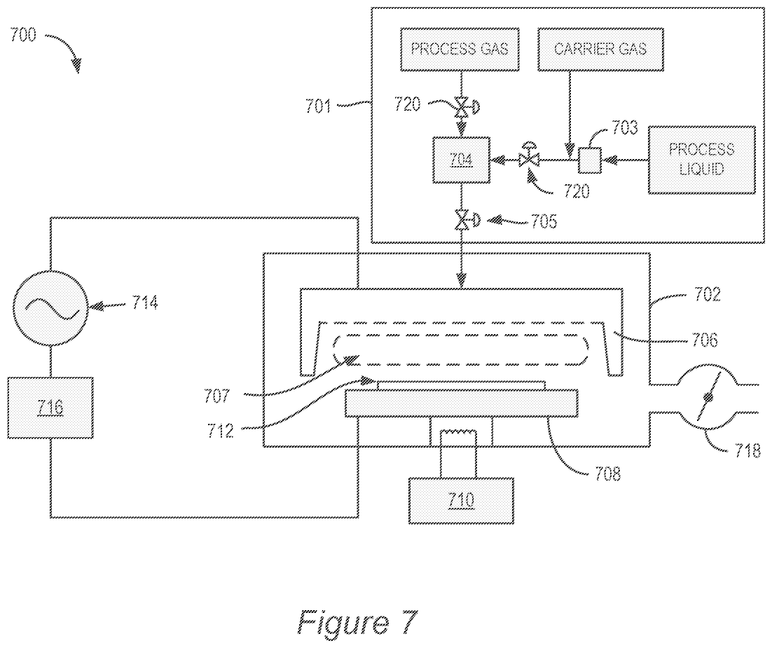

An example of a deposition apparatus suitable for depositing molybdenum-containing films using provided methods is shown in FIG. 7. FIG. 7 schematically shows an embodiment of a process station 700 that may be used to deposit material using atomic layer deposition (ALD) and/or chemical vapor deposition (CVD), either of which may be plasma enhanced. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers.

Process station 700 fluidly communicates with reactant delivery system 701 for delivering process gases to a distribution showerhead 706. Reactant delivery system 701 includes a mixing vessel 704 for blending and/or conditioning process gases for delivery, to showerhead 706. One or more mixing vessel inlet valves 720 may control introduction of process gases to mixing vessel 704. Similarly, a showerhead inlet valve 705 may control introduction of process gasses to the showerhead 706.

Some molybdenum-containing precursors may be stored in solid or liquid form prior to vaporization and subsequent delivery to the process station. For example, the embodiment of FIG. 7 includes a vaporization point 703 for vaporizing solid reactant to be supplied to mixing vessel 704. In some embodiments, vaporization point 703 may be a heated vaporizer. In some embodiments a flow of an inert gas is passed over the heated solid molybdenum precursor, or bubbled through the heated liquid molybdenum precursor, under sub-atmospheric pressure, and carries the precursor vapor to the process chamber. The precursor vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 200° C. at mixing vessel 704.

Showerhead 706 distributes process gases toward substrate 712. In the embodiment shown in FIG. 7, substrate 712 is located beneath showerhead 706, and is shown resting on a pedestal 708. It will be appreciated that showerhead 706 may have any suitable shape, and may have any suitable number and arrangement of ports for distributing processes gases to substrate 712. While not explicitly shown, in some embodiments the showerhead 700 is a dual plenum showerhead that includes at least two types of conduits, where the first type of conduit is dedicated to delivery of molybdenum-containing precursor vapor, and the second type of conduit is dedicated to delivery of the second (or other) reactant. In these embodiments the molybdenum-containing precursor and the reactant are not allowed to mix in the conduits prior to entry to the process chamber, and do not share the conduits if delivered to the chamber consecutively.

In some embodiments, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some embodiments, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 706 may be adjusted relative to pedestal 708 to van, a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering a plasma. In other embodiments apparatuses without a plasma generator are used for depositing molybdenum-containing films using provided methods. In some embodiments, the plasma energy may be controlled by controlling one or more of a process station pressure, a gas concentration, a radio frequency (RF) source power, an RF source frequency, and a plasma power pulse timing. For example, RF power supply 714 and matching network 716 may be operated at any suitable power to form a plasma having a desired composition of radical species. Likewise, RF power supply 714 may provide RF power of any suitable frequency. In some embodiments, RF power supply 714 may be configured to control high- and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 708 may be temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to process station 700.

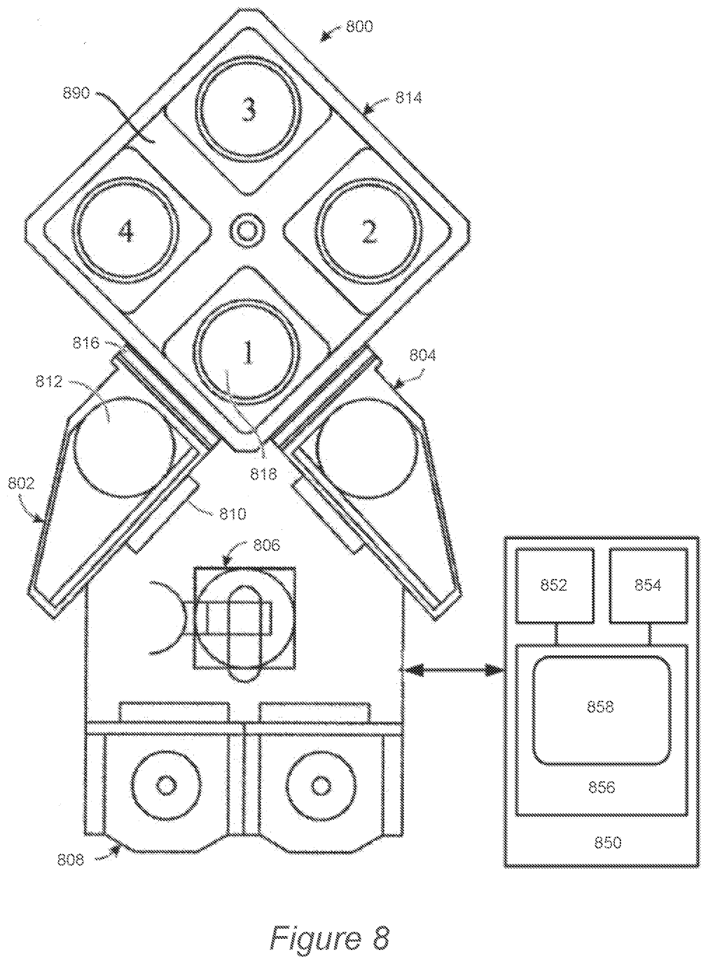

FIG. 8 shows a schematic view of an embodiment of a multi-station processing tool 800 with an inbound load lock 802 and an outbound load lock 804, either or both of which may comprise a remote plasma source. Such tool may be used for processing the substrates using the methods provided herein. A robot 806, at atmospheric pressure, is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 comprises a remote plasma source, the wafer may be exposed to a remote plasma treatment in the load lock prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc.

In some embodiments, system controller 850 controls all of the activities of process tool 800. System controller 850 executes system control software 858 stored in mass storage device 854, loaded into memory device 856, and executed on processor 852. System control software 858 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 800. System control software 858 may be configured in any suitable way. For example, various process tool component subroutines or control objects may be written to control operation of the process tool components necessary to carry out various process tool processes in accordance with the disclosed methods. System control software 858 may be coded in any suitable computer readable programming language.

In some embodiments, system control software 858 may include input/output control (IOC) sequencing instructions for controlling the various parameters described above. For example, each phase of an ALD process may include one or more instructions for execution by system controller 850. The instructions for setting process conditions for an ALD process phase may be included in a corresponding ALD recipe phase. In some embodiments, the ALD recipe phases may be sequentially arranged, so that all instructions for a ALD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the Altus® product family, available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

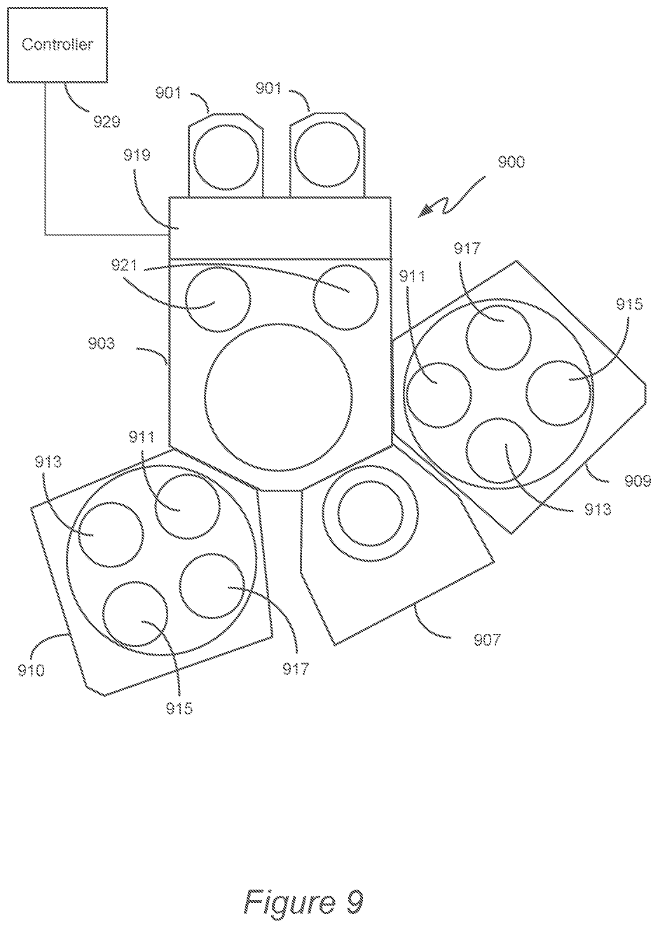

FIG. 9 is a block diagram of a processing system suitable for conducting thin film deposition processes in accordance with certain embodiments. The system 900 includes a transfer module 903. The transfer module 903 provides a clean, pressurized environment to minimize risk of contamination of substrates being processed as they are moved between various reactor modules. Mounted on the transfer module 903 are two multi-station reactors 909 and 910, each capable of performing atomic layer deposition (ALD) and/or chemical vapor deposition (CVD) according to certain embodiments. Reactors 909 and 910 may include multiple stations 911, 913, 915, and 917 that may sequentially or non-sequentially perform operations in accordance with disclosed embodiments. The stations may include a heated pedestal or substrate support, one or more gas inlets or showerhead or dispersion plate.

Also mounted on the transfer module 903 may be one or more single or multi-station modules 907 capable of performing plasma or chemical (non-plasma) pre-cleans, or any other processes described in relation to the disclosed methods. The module 907 may in some cases be used for various treatments to, for example, prepare a substrate for a deposition process. The module 907 may also be designed/configured to perform various other processes such as etching or polishing. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the silicon-containing reagent flow, reducing agent flow, and metal-containing precursor flow, and other processes in a process sequence can be written in any conventional computer readable programming language; for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### Experimental Examples

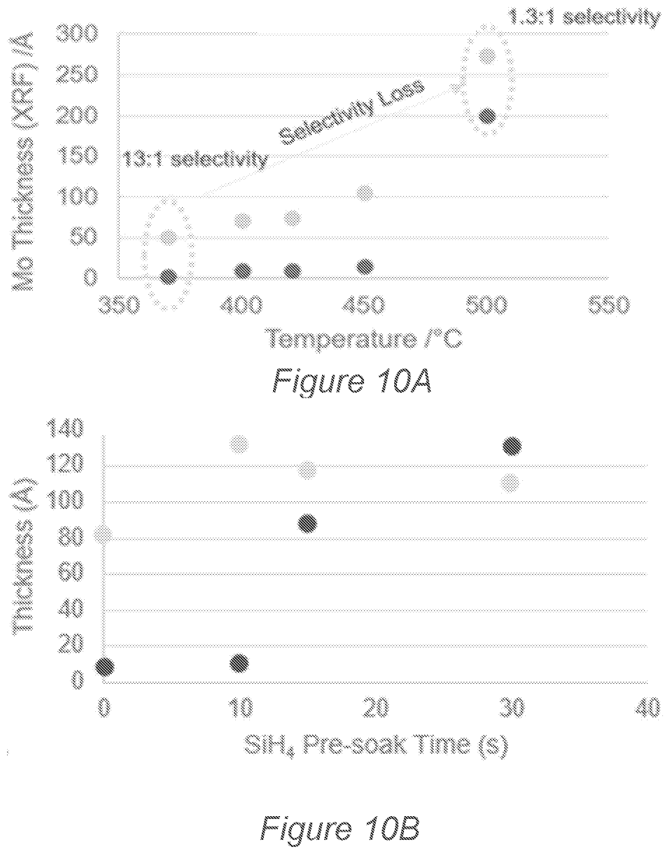

Example 1 (comparative). Molybdenum metal was deposited on a dielectric (silicon oxide) and on a metal (low fluorine tungsten) using a sequence of silicon-free deposition cycles. Each cycle included a first exposure phase, where MoCl₅ and hydrogen were delivered to the process chamber and were allowed to contact the substrate) and a second exposure phase, where hydrogen was delivered to the process chamber in an absence of molybdenum precursor delivery. The depositions were conducted by performing 200 deposition cycles at different temperatures ranging from 375° C. to 500° C. Thickness of deposited molybdenum was measured by XRF (X-ray fluorescence). FIG. 10A provides a plot illustrating molybdenum thickness obtained at each temperature. The upper point for each temperature refers to deposition on tungsten. The lower point for each temperature refers to deposition on dielectric. At all temperatures the deposited thickness on tungsten is greater than on dielectric. It can be seen that on-metal/on-dielectric selectivity (the ratio of molybdenum thickness deposited on tungsten to a thickness deposited on dielectric) is very high at temperatures lower than 500° C., reaching 13 at 375° C. The selectivity is reduced with increasing temperatures and selectivity of 1.3 is achieved at 500° C. This plot illustrates that at temperatures of less than 500° C., selectivities of lower than 1.3 could not be achieved.

Example 2. In accordance with embodiments provided herein, silicon-assisted deposition of molybdenum-containing material was conducted on tungsten and on silicon oxide at 400° C. Each cycle of silicon-assisted deposition included three phases. In a first phase, silane (SiH₄) was delivered to the process chamber and the substrate was allowed to contact silane for a pre-determined time (ranging from 10 to 30 seconds) in an absence of hydrogen delivery and in an absence of molybdenum precursor delivery. This phase is referred to as silane pre-soak. In a second phase, MoCl₅, and H₂ were delivered to the process chamber contemporaneously and allowed to contact the substrate. In a third phase, H₂ was delivered to the process chamber without contemporaneous delivery of a molybdenum precursor. The deposition was conducted by performing 200 cycles of silicon-assisted deposition, where each cycle included a silane pre-soak phase, a molybdenum precursor with hydrogen delivery phase, and hydrogen delivery phase. The thicknesses of the resulting molybdenum-containing films were measured by XRF. FIG. 10B is a plot illustrating the thicknesses of the molybdenum-containing material deposited on tungsten and on silicon dioxide for different durations of silane pre-soak. The upper points refer to deposition on tungsten. The lower points refer to deposition on silicon dioxide. It can be seen that pre-soak times of less than 15 seconds did not lead to significant on-metal/on-dielectric selectivity loss, whereas for the pre-soak duration of 15 seconds and 30 seconds the selectivities were 1.33 and 1.20, respectively. It is noted that such low selectivities were not attainable at a low temperature of 400° C. using silicon-free deposition. This example illustrates selectivity loss obtained at low temperatures using silicon-assisted deposition provided herein.

1. A method of forming a molybdenum-containing layer, the method comprising:
(a) providing a semiconductor substrate having a recessed feature to a process chamber; and
(b) exposing the semiconductor substrate to a molybdenum-containing precursor, a reducing agent, and a silicon-containing reactant at a temperature of between about 100 and about 500° C. to reduce the molybdenum-containing precursor and form a molybdenum-containing layer on the semiconductor substrate, wherein the molybdenum-containing layer comprises a layer of molybdenum metal.

2. The method of claim 1, wherein the molybdenum-containing layer further comprises a sub-layer of molybdenum silicide.

3. The method of claim 1, wherein the molybdenum-containing precursor is MoXₙYₘ, wherein X is a chalcogen, Y is a halogen, n is 0, 1, or 2, and m is 2, 3, 4, 5 or 6.

4. The method of claim 1, wherein the molybdenum-containing precursor comprises MoCl₅, Mo₂Cl₁₀, MoO₂Cl₂, MoOCl₄, bis(ethylbenzene)molybdenum or any combination thereof.

5. The method of claim 1, wherein the silicon-containing reactant is SiₓR_{y}, wherein x is 1-4, y is 4-18, and each R is independently selected from the group consisting of H, a halogen, and an alkyl.

6. The method of claim 1, wherein the silicon-containing reactant comprises silane, chlorosilane, dichlorosilane, trichlorosilane, tetrachlorosilane, hexachlorodisilane, pentachlorodisilane, tetrachlorodisilane, trichlorodisilane dichlorodisilane, chlorodisilane, disilane or any combination thereof.

7. The method of claim 1, wherein (b) comprises:
(i) contacting the semiconductor substrate with the silicon-containing reactant for a period of time without contemporaneously delivering the molybdenum-containing precursor to the process chamber; and
(ii) after (i), contacting the semiconductor substrate with the molybdenum-containing precursor and with the reducing agent.

8. The method of claim 7, wherein (ii) comprises contacting the semiconductor substrate with the molybdenum-containing precursor without contemporaneously delivering the reducing agent to the process chamber or wherein (ii) comprises contemporaneously contacting the semiconductor substrate with the molybdenum-containing precursor and with the reducing agent.

9. (canceled)

10. (canceled)

11. The method of claim 7, wherein (ii) comprises sequentially contacting the semiconductor substrate with the molybdenum-containing precursor and with the reducing agent, and repeating the sequential contacting with the molybdenum-containing precursor and the reducing agent, further comprising (iii) contacting the semiconductor substrate with the silicon-containing reactant after (ii).

12. The method of claim 1, wherein (b) comprises contemporaneously contacting the semiconductor substrate with the reducing agent, the molybdenum-containing precursor and the silicon-containing reactant.

13. The method of claim 1, wherein (b) comprises:
(i) contacting the semiconductor substrate with the reducing agent and the silicon-containing reactant contemporaneously; and
(ii) contacting the semiconductor substrate with the molybdenum-containing precursor without contemporaneously delivering the silicon-containing reactant to the process chamber.

14. The method of claim 1, wherein (b) comprises:
(i) contacting the semiconductor substrate with the molybdenum-containing precursor and the silicon-containing reactant contemporaneously; and
(iii) contacting the semiconductor substrate with the reducing agent without contemporaneously delivering the silicon-containing reactant to the process chamber.

15. The method of claim 1, wherein the recessed feature provided in (a) comprises an exposed silicon-containing dielectric on sidewalls of the recessed feature, and a metal exposed at a bottom of the recessed feature, wherein the molybdenum-containing layer is deposited both on the bottom of the recessed feature and on the sidewalls of the recessed features with a selectivity of about 1.3:1 (bottom to sidewalls) or less.

16. The method of claim 1, wherein (b) comprises completely filling the recessed feature with the molybdenum-containing layer, wherein the molybdenum-containing layer comprises a molybdenum metal layer.

17. (canceled)

18. (canceled)

19. An apparatus for processing a semiconductor substrate, the apparatus comprising:
(a) a process chamber, having a substrate holder for holding the semiconductor substrate and one or more inlets for introduction of reactants to the process chamber; and
(b) a controller comprising program instructions for:
on a semiconductor substrate having a recessed feature, causing contact of the semiconductor substrate with a molybdenum-containing precursor, a reducing agent, and a silicon-containing reactant at a temperature of between about 100 and about 500° C. to form a layer of molybdenum-containing material.

20. The apparatus of claim 19, wherein the program instructions comprise instructions configured to cause:
(i) contacting of the semiconductor substrate with the silicon-containing reactant without contemporaneously delivering the molybdenum-containing precursor to the process chamber; and
(ii) after (i) contacting the semiconductor substrate with the molybdenum-containing precursor and the reducing agent.

21. The apparatus of claim 19, wherein the program instructions comprise instructions configured to cause:
(i) contemporaneously contacting the semiconductor substrate with hydrogen and the silicon-containing reactant without contemporaneously delivering the molybdenum-containing precursor to the process chamber; and
(ii) contacting the semiconductor substrate with the molybdenum-containing precursor without contemporaneously delivering the silicon-containing reactant to the process chamber.

22. The apparatus of claim 19, wherein the program instructions comprise instructions configured to cause:
(i) contemporaneously contacting the semiconductor substrate with the molybdenum-containing precursor and the silicon-containing reactant without contemporaneously delivering hydrogen to the process chamber; and
(ii) contacting the semiconductor substrate with hydrogen without contemporaneously delivering the silicon-containing reactant to the process chamber.

23. A method of forming a metal-containing layer, the method comprising:
(a) providing a semiconductor substrate having a recessed feature to a process chamber; and
(b) exposing the semiconductor substrate to a metal precursor, a reducing agent, and a silicon-containing reactant at a temperature of between about 100 and about 500° C. to reduce the metal precursor and form a metal-containing layer on the semiconductor substrate, wherein the metal-containing layer comprises a layer of metal in zero oxidation state.

24. The method of claim 23, wherein the metal-containing layer further comprises a layer of metal silicide.
